(19) United States
(12) Patent Application Publication
(10) Pub. No.: US 2021/0171690 A1
(43) Pub. Date: Jun. 10, 2021

(54) PHOTOSENSITIVE RESIN COMPOSITION, CURED FILM, LAMINATE, TRANSFER FILM, AND MANUFACTURING METHOD OF TOUCH PANEL

(71) Applicant: FUJIFILM Corporation, Tokyo (JP)

(72) Inventors: Tatsuya SHIMOYAMA, Fujinomiya-shi (JP); Kentaro Toyooka, Fujinomiya-shi (JP)

(73) Assignee: FUJIFILM Corporation, Tokyo (JP)

(21) Appl. No.: 17/178,332

(22) Filed: Feb. 18, 2021

Related U.S. Application Data
(63) Continuation of application No. PCT/JP2019/027147, filed on Jul. 9, 2019.

(30) Foreign Application Priority Data
Sep. 20, 2018 (JP) 2018-176454

(51) Int. Cl. C08F 265/06; G03F 7/033; G06F 3/044

(52) U.S. Cl. CPC C08F 265/06; G06F 2203/04103; G06F 3/044; G03F 7/033

(57) ABSTRACT

A photosensitive resin composition includes: a binder polymer; an ethylenically unsaturated compound having no blocked isocyanate group, a photopolymerization initiator, and a blocked isocyanate compound, in which the blocked isocyanate compound has a carboxylic acid group.

### CROSS-REFERENCE TO RELATED APPLICATIONS

This application is a Continuation of PCT International Application No. PCT/JP2019/027147 filed on Jul. 9, 2019, which claims priority under 35 U.S.C § 119(a) to Japanese Patent Application No. 2018-176454 filed on Sep. 20, 2018. Each of the above application(s) is hereby expressly incorporated by reference, in its entirety, into the present application.

### BACKGROUND OF THE INVENTION

### 1. Field of the Invention

The present disclosure relates to a photosensitive resin composition, a cured film, a laminate, a transfer film, and a manufacturing method of a touch panel.

### 2. Description of the Related Art

In recent years, in electronic devices such as a mobile phone, a car navigator, a personal computer, a ticket vending machine, or a terminal of the bank, a tablet type input device is disposed on a surface of a liquid crystal device or the like. There is provided a device to which information corresponding to an instruction image is input, by touching a portion, where the instruction image is displayed, with fingers or a touch pen, while referring to the instruction image displayed in an image display region of a liquid crystal device.

The input device described above (hereinafter, may be referred to as a touch panel) may include a resistance film type input device, a capacitive input device, and the like. The capacitive input device is advantageous in that a transmittance conductive film may be simply formed on one sheet of substrate. In such a capacitive input device, there is provided a device in which electrode patterns are extended in directions intersecting each other, and which detects an input position by detecting a change of electrostatic capacity between electrodes, in a case where a finger or the like is touched.

In order to protect electrode patterns or leading wirings (for example, metal wirings such as copper wires) put together on a frame portion of the capacitive input device, a transparent resin layer is provided on a side opposite to the surface for the inputting with a finger or the like.

In a case using these capacitive input devices, in a case of visually recognizing a surface of a touch panel on a position slightly separated from a vicinity of a regular reflected portion of incident light from a light source, transparent electrode patterns present inside are visually recognized, and this may become an appearance defect. Accordingly, it is necessary to improve concealing properties of the transparent electrode patterns on the surface of a touch panel or the like.

In addition, examples of the transfer film of the related art include those disclosed in WO2018/105313A.

WO2018/105313A discloses a transfer film including: a temporary support, and a photosensitive transparent resin layer positioned on the temporary support, in which the photosensitive transparent resin layer includes a binder polymer, an ethylenically unsaturated compound, a photopolymerization initiator, and a compound capable of reacting with acid by heating, and the compound capable of reacting with acid by heating has a polymerizable group.

### SUMMARY OF THE INVENTION

An object to be solved by an embodiment of the invention is to provide a photosensitive resin composition having excellent developability and a low moisture permeability of a cured film to be obtained.

Another object to be achieved by another embodiment of the invention is to provide a cured film formed of the photosensitive resin composition, a laminate, a transfer film, and a manufacturing method of a touch panel.

Methods for achieving the objects described above include the following aspects.

<1> A photosensitive resin composition comprising: a binder polymer; an ethylenically unsaturated compound having no blocked isocyanate group, a photopolymerization initiator, and a blocked isocyanate compound, in which the blocked isocyanate compound has a carboxylic acid group.

<2> The photosensitive resin composition according to <1>, in which the blocked isocyanate compound further includes a polymerizable group.

<3> The photosensitive resin composition according to <2>, in which the polymerizable group in the blocked isocyanate compound is an ethylenically unsaturated group.

<4> The photosensitive resin composition according to <2> or <3>, in which a value of a ratio N_{C}/N_{B} of a functional group number N_{C} of carboxylic acid groups included in the blocked isocyanate compound to a total N_{B} of a functional group number of blocked isocyanate groups and a functional group number of the polymerizable groups included in the blocked isocyanate compound is 0.1 or more.

<5> The photosensitive resin composition according to any one of <1> to <4>, in which a weight-average molecular weight of the blocked isocyanate compound is 500 or more.

<6> The photosensitive resin composition according to any one of <1> to <5>, in which a content of the blocked isocyanate compound is 5% by mass or more with respect to a total solid content of the photosensitive resin composition.

<7> The photosensitive resin composition according to any one of <1> to <6>, in which the binder polymer is an alkali-soluble resin having an acid value of 60 mgKOH/g or more.

<8> The photosensitive resin composition according to any one of <1> to <7>, in which the binder polymer is a resin having a constitutional unit including an ethylenically unsaturated group.

<9> A cured film obtained by curing a solid content of the photosensitive resin composition according to any one of <1> to <8>.

<10> The cured film according to <9>, which is a protective film for a touch panel.

<11> A laminate formed by laminating a substrate, an electrode, and the cured film according to <8> or <9> in order.

<12> The laminate according to <11>, in which the electrode is an electrode of a capacitive input device.

<13> A transfer film comprising: a temporary support; and a layer including the photosensitive resin composition according to any one of <1> to <8>.

<14> A manufacturing method for a touch panel comprising: preparing a substrate for a touch panel having a structure in which at least one of an electrode for a touch panel or a wiring for a touch panel is disposed on the substrate; forming a photosensitive layer on a surface of the substrate for a touch panel on a side where at least one of the electrode for a touch panel or the wiring for a touch panel is disposed, using the transfer film according to <13>; performing patternwise exposing on the photosensitive layer formed on the substrate for a touch panel to light; and developing the patternwise exposed photosensitive layer to obtain a protective film for a touch panel which protects at least a part of at least one of the electrode for a touch panel or the wiring for a touch panel.

According to an embodiment of the invention, it is possible to provide a photosensitive resin composition having excellent developability and a low moisture permeability of a cured film to be obtained.

According to another embodiment of the invention, it is possible to provide a cured film formed of the photosensitive resin composition, a laminate, a transfer film, and a manufacturing method of a touch panel.

### BRIEF DESCRIPTION OF THE DRAWINGS

FIG. 1 is a schematic cross sectional view showing an example of a transfer film according to the disclosure.

FIG. 2 is a schematic cross sectional view showing a first specific example of a touch panel according to the disclosure.

FIG. 3 is a schematic cross sectional view showing a second specific example of the touch panel according to the disclosure.

### DESCRIPTION OF THE PREFERRED EMBODIMENTS

Hereinafter, the content of the disclosure will be described in detail. The configuration elements will be described below based on the representative embodiments of the disclosure, but the disclosure is not limited to such embodiments.

In the disclosure, a term “to” showing a range of numerical values is used as a meaning including a lower limit value and an upper limit value disclosed before and after the term.

In a range of numerical values described in stages in this specification, the upper limit value or the lower limit value described in one range of numerical values may be replaced with an upper limit value or a lower limit value of the range of numerical values described in other stages. In addition, in a range of numerical values described in this specification, the upper limit value or the lower limit value of the range of numerical values may be replaced with values shown in the examples.

Regarding a term, group (atomic group) of this disclosure, a term with no description of “substituted” and “unsubstituted” includes both a group not including a substituent and a group including a substituent. For example, an “alkyl group” not only includes an alkyl group not including a substituent (unsubstituted alkyl group), but also an alkyl group including a substituent (substituted alkyl group).

In the specification, a “total solid content” refers to a total mass of components excluding a solvent from the entire composition. In addition, the “solid content” is a component excluding the solvent, as described above, and may be a solid or a liquid at 25° C., for example.

In addition, in the disclosure, “% by mass” is identical to “% by weight” and “part by mass” is identical to “part by weight”.

Further, in the disclosure, a combination of two or more preferable embodiments is the more preferable embodiments.

In the disclosure, in a case where a plurality of substances corresponding to components are present in a composition, an amount of each component in the composition means a total amount of the plurality of substances present in the composition, unless otherwise noted.

In the disclosure, a term “step” not only includes an independent step, but also includes a step, in a case where the step may not be distinguished from the other step, as long as the expected object of the step is achieved.

In the disclosure, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

A weight-average molecular weight (Mw) and a number average molecular weight (Mn) of the disclosure, unless otherwise noted, are detected by a gel permeation chromatography (GPC) analysis device using a column of TSKgel GMHxL, TSKgel G4000HxL, TSKgel G2000HxL (all product names manufactured by Tosoh Corporation), by using tetrahydrofuran (THF) as a solvent and a differential refractometer, and are molecular weights obtained by conversion using polystyrene as a standard substance.

In the disclosure, a ratio of the constitutional unit in a resin represents a molar ratio unless otherwise noted.

In the disclosure, the molecular weight, in a case where there is a molecular weight distribution, represents the weight-average molecular weight (Mw), unless otherwise noted.

Hereinafter, the disclosure will be described in detail.

(Photosensitive Resin Composition)

The photosensitive resin composition according to the disclosure includes: a binder polymer; an ethylenically unsaturated compound having no blocked isocyanate group, a photopolymerization initiator, and a blocked isocyanate compound, and the blocked isocyanate compound has a carboxylic acid group.

As a result of intensive studies, the inventors have found that it is possible to provide a photosensitive resin composition having excellent developability and low moisture permeability of a cured film to be obtained, by using the above configuration.

An operation mechanism for excellent effect by this is not clear, but is assumed as follows.

A blocked group is dissociated from the blocked isocyanate compound having a carboxylic acid group during heat treatment (baking), and the generated isocyanate group reacts with a polar group such as a binder polymer to reduce the moisture permeability of the cured film to be obtained. In addition, it is surmised that, at the time of baking, the carboxylic acid group of the blocked isocyanate compound forms an acid anhydride intramolecularly or intermolecularly with other carboxylic acid groups, thereby being reduced in hydrophilicity, which suppresses an increase in moisture permeability, but the carboxylic acid group functions as a hydrophilic group during development, thereby exhibiting excellent developability.

Hereinafter, the photosensitive resin composition according to the disclosure will be described in detail.

<Blocked Isocyanate Compound>

The photosensitive resin composition according to the disclosure includes a blocked isocyanate compound, and the blocked isocyanate compound includes a carboxylic acid group.

The blocked isocyanate compound refers to a “compound having a structure in which the isocyanate group of isocyanate is protected (masked) with a blocking agent”.

The number of blocked isocyanate groups in the blocked isocyanate compound may be 1 or more, but from viewpoints of a balance between developability and moisture permeability, curability, and strength of the cured film to be obtained, the number thereof is preferably 1 to 10, more preferably 1 to 4, and particularly preferably 1 or 2.

A dissociation temperature of the blocked isocyanate group in the blocked isocyanate compound is preferably 100° C. to 160° C. and more preferably 130° C. to 150° C.

The dissociation temperature of the blocked isocyanate group of the specification is a “temperature at an endothermic peak accompanied with a deprotection reaction of the blocked isocyanate group, in a case where the measurement is performed by differential scanning calorimetry (DSC) analysis using a differential scanning calorimeter (manufactured by Seiko Instruments Inc., DSC6200)”.

Examples of the blocking agent having the dissociation temperature at 100° C. to 160° C. include a pyrazole compound (3,5-dimethylpyrazole, 3-methylpyrazole, 4-bromo-3,5-dimethylpyrazole, or 4-nitro-3,5-dimethylpyrazole, and the like), an active methylene compound (diester malonate (dimethyl malonate, diethyl malonate, di n-butyl malonate, di-2-ethylhexyl malonate)), a triazole compound (1,2,4-triazole), and an oxime compound (compound having a structure represented by —C(═N—OH)— in a molecule such as formaldoxime, acetoaldoxime, acetoxime, methyl ethyl ketoxime, cyclopentanoneoxime, or cyclohexanone oxime). Among these, from a viewpoint of preservation stability, an oxime compound or a pyrazole compound is preferable, and an oxime compound is particularly preferable.

The number of carboxylic acid groups (carboxylic groups) in the blocked isocyanate compound including the carboxylic acid group used in the disclosure may be 1 or more, but from a viewpoint of a balance between developability and moisture permeability, the number thereof is preferably 1 to 10, more preferably 1 to 4, and particularly preferably 1 or 2.

In addition, the carboxylic acid group may be an aliphatic carboxylic acid group or an aromatic carboxylic acid group, but from a viewpoint of developability, it is preferably an aliphatic carboxylic acid group.

Further, the blocked isocyanate compound preferably has a 1,2-dicarboxylic acid structure or a 1,3-dicarboxylic acid structure, and more preferably 1,2-dicarboxylic acid structure, from a viewpoint of reducing the moisture permeability of the cured film to be obtained. With the structure described above, it is easy to form an acid anhydride in a molecule during heat treatment (baking), and accordingly, the moisture permeability of the cured film to be obtained can be further reduced.

The blocked isocyanate compound used in the disclosure preferably has a polymerizable group and more preferably has a radically polymerizable group, from viewpoints of hardness and moisture permeability after curing.

The polymerizable group is not particularly limited, and well-known polymerizable groups can be used, and examples thereof include a (meth)acryloxy group, a (meth)acrylamide group, an ethylenically unsaturated group such as styryl group, and an epoxy group such as a glycidyl group. Among these, as the polymerizable group, an ethylenically unsaturated group is preferable, and a (meth)acryloxy group is more preferable, from viewpoints of moisture permeability of the cured film to be obtained, surface shape of the surface of the cured film to be obtained, a development speed, and reactivity.

In a case where the blocked isocyanate compound has a polymerizable group, a value of a ratio N_{C}/N_{B} of a functional group number N_{C} of the carboxylic acid groups included in the blocked isocyanate compound to a total N_{B} of a functional group number of the blocked isocyanate groups and a functional group number of the polymerizable groups included in the blocked isocyanate compound is preferably 0.05 or more, more preferably 0.1 or more, even more preferably 0.1 to 1, and particularly preferably 0.2 to 0.8, from a viewpoint of developability.

The blocked isocyanate compound may be not only a monomer but also an oligomer or a polymer.

The molecular weight of the blocked isocyanate compound is preferably 300 or more, more preferably 500 or more, even more preferably 700 to 4,000, and particularly preferably 800 to 3,000, from viewpoints of the moisture permeability of the cured film to be obtained, and the handleability of a transfer film.

In addition, the blocked isocyanate compound preferably has at least one kind of a structure selected from the group consisting of a biuret bond, an allophanate bond, and an isocyanuric ring structure, and more preferably an allophanate bond, from viewpoints of developability and moisture permeability of the cured film to be obtained.

The biuret bond, allophanate bond, and isocyanuric ring structure are shown below.

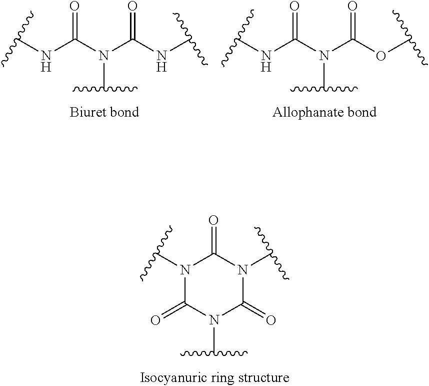 [SMILES: *NC(=O)N(*)C(=O)N* ; *NC(=O)N(*)C(=O)O* ; *n1c(=O)n(*)c(=O)n(*)c1=O]

In the above structure, a wavy line part represents a bonding position with another structure.

From a viewpoint of hardness and moisture permeability after curing, the blocked isocyanate compound preferably has a partial structure represented by Formula (B-1), more preferably has a partial structure represented by Formula (B-2), and particularly preferably has a partial structure represented by Formula (B-3).

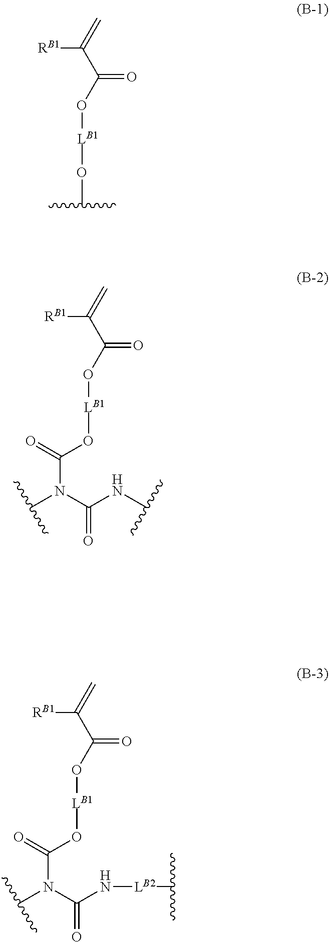

In Formulae (B-1) to (B-3), R^{B1} represents a hydrogen atom or a methyl group, L^{B1} represents an alkylene group having 2 to 8 carbon atoms, and L^{B2} represents an alkylene group, an arylene group, or a divalent group in which one or more alkylene groups and one or more arylene groups are bonded.

R^{B1} in Formulae (B-1) to (B-3) is preferably a hydrogen atom, from viewpoints of curability and strength of the cured film to be obtained.

The alkylene group for L^{B1} in Formulae (B-1) to (B-3) may be linear, branched, or cyclic, it is preferably a linear alkylene group.

In addition, from a viewpoint of developability, L^{B1} in Formulae (B-1) to (B-3) is preferably an alkylene group having 2 to 4 carbon atoms, more preferably an alkylene group having 2 or 3 carbon atoms, and particularly preferably an ethylene group.

From a viewpoint of developability, L^{B2} in Formula (B-3) is preferably an alkylene group or a divalent group in which one or more alkylene groups and one or more arylene groups are bonded.

The number of carbon atoms of L^{B2} in Formula (B-3) is preferably 4 to 12 and more preferably 5 to 10.

The alkylene group of L^{B2} in Formula (B-3) may be linear, branched, or cyclic, but it is preferably a linear alkylene group or a cyclic alkylene group.

In addition, the blocked isocyanate compound preferably has a partial structure represented by Formula (B-3) as a constitutional repeating unit, from viewpoints of hardness and moisture permeability after curing. The number of repetitions of the partial structure represented by Formula (B-3) is preferably 2 to 20, more preferably 2 to 10, and particularly preferably 2 to 4, from viewpoints of hardness and moisture permeability after curing.

Specific preferred examples of the blocked isocyanate compound are shown below, but it is needless to say that the invention is not limited thereto. The molecular weight of each compound is also shown.

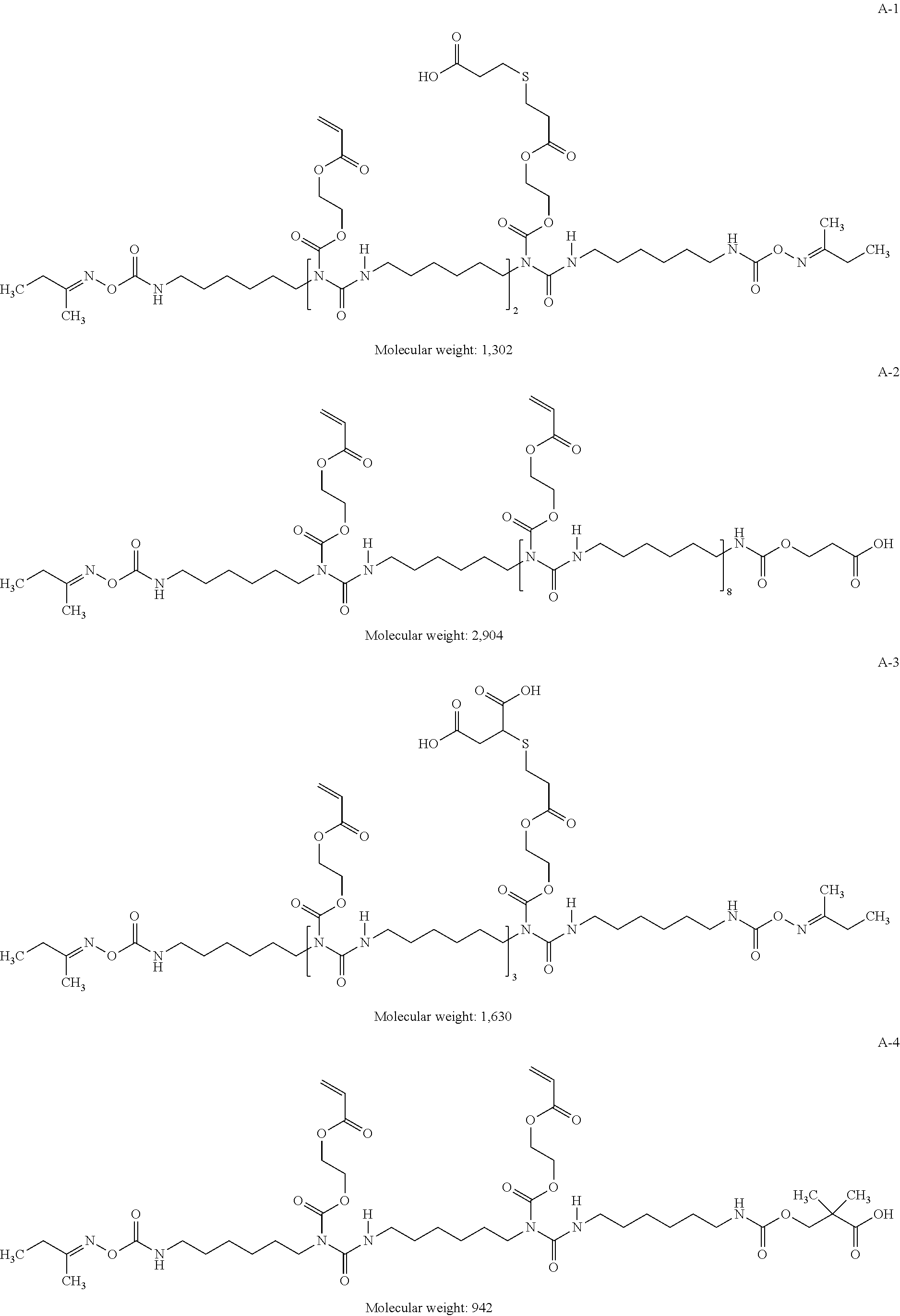

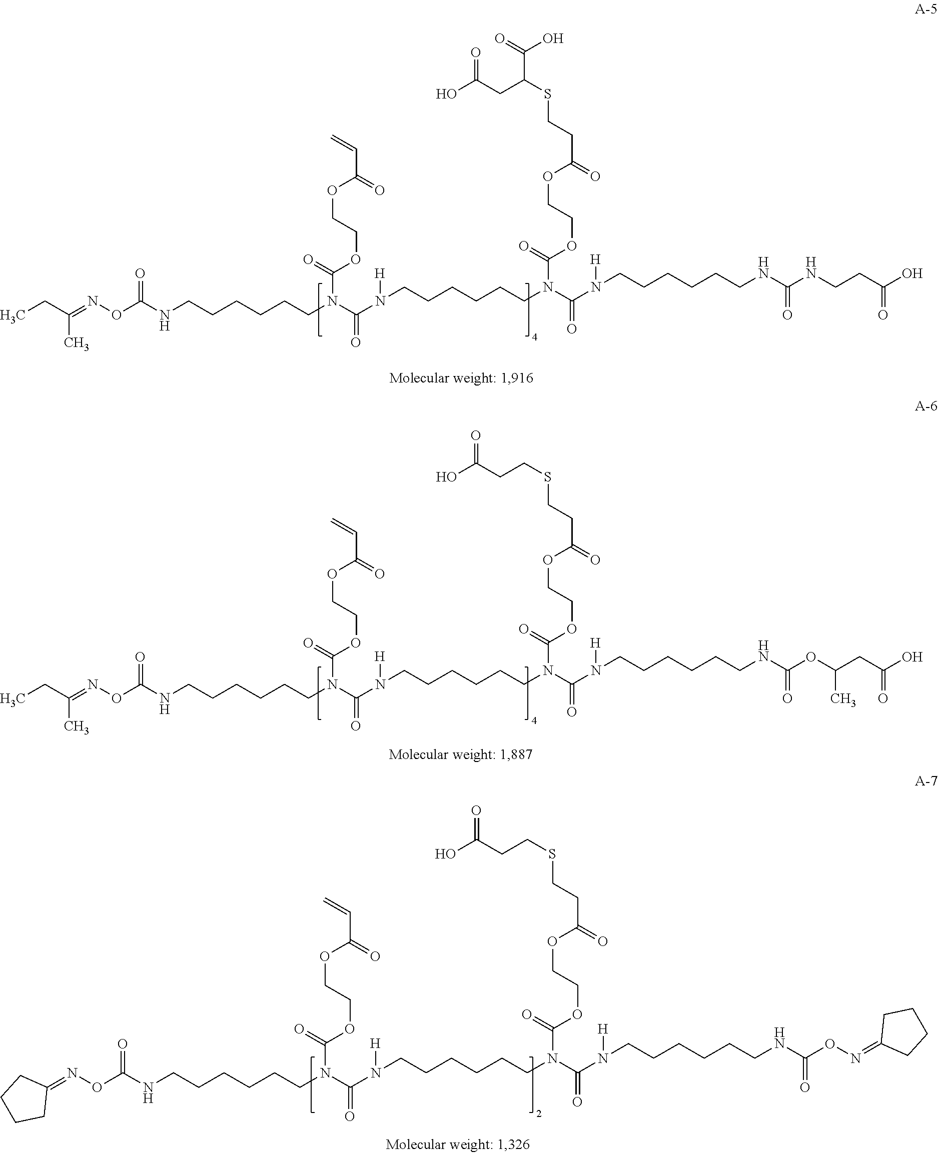

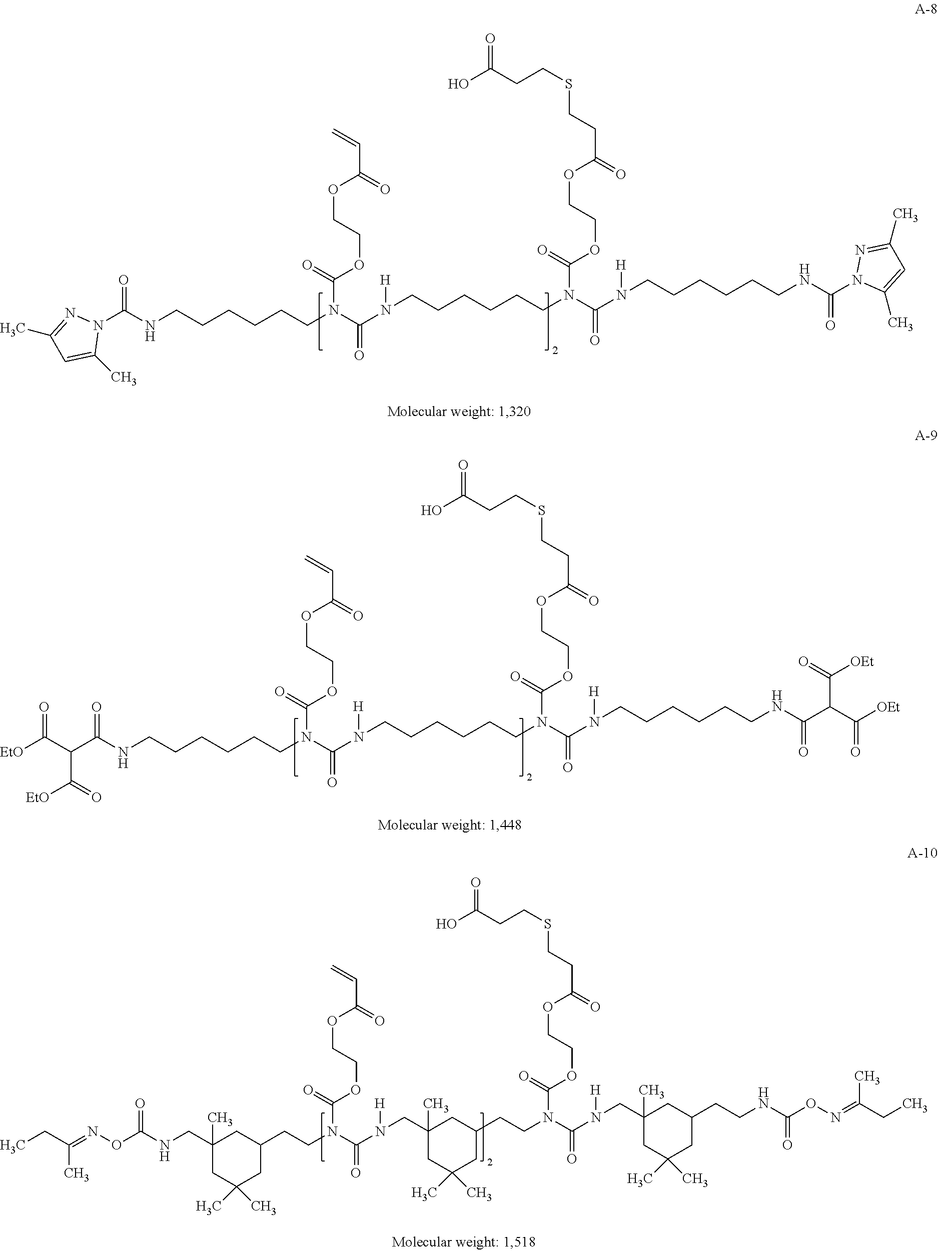

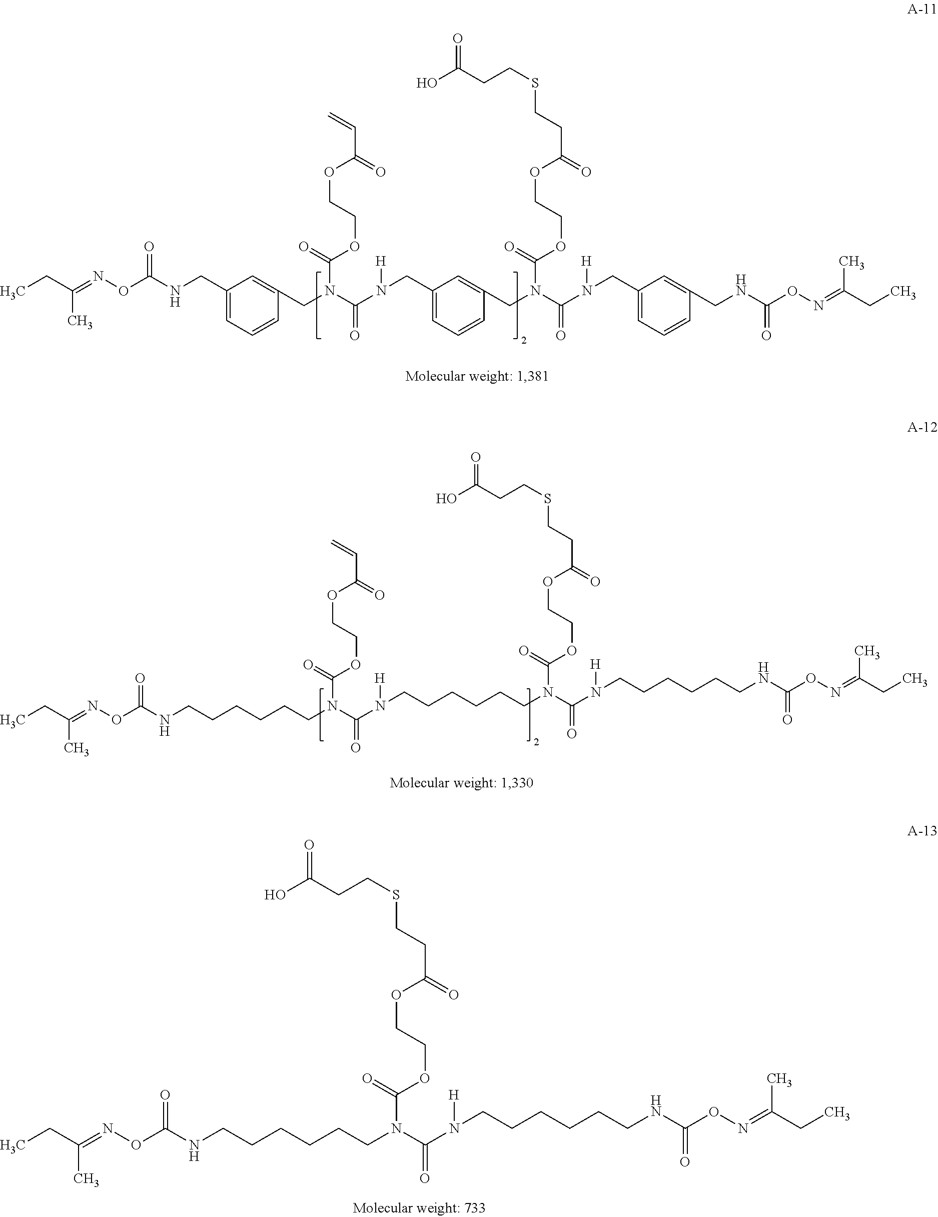

Et in the above compound represents an ethyl group.

A method for synthesizing the blocked isocyanate compound is not particularly limited and the blocked isocyanate compound may be synthesized by referring to a well-known method. For example, a method for introducing each of a carboxylic acid group and a polymerizable group with respect to a blocked isocyanate compound not having a carboxylic acid group, a method for introducing a carboxylic acid group with respect to a blocked isocyanate compound having a polymerizable group and not having a carboxylic acid group, and the like are used.

In the disclosure, the blocked isocyanate compound may be used alone or in combination of two or more kinds thereof.

A content of the blocked isocyanate compound is preferably 1% by mass to 50% by mass, more preferably 2% by mass to 30% by mass, even more preferably 4% by mass to 25% by mass, and particularly preferably 5% by mass to 25% by mass with respect to a total solid content of the photosensitive resin composition, from viewpoints of developability, moisture permeability of the cured film to be obtained, and strength of the cured film to be obtained.

In addition, the photosensitive resin composition according to the disclosure may include a blocked isocyanate compound not having a carboxylic acid group. However, in this case, from viewpoints of developability and moisture permeability of the cured film to be obtained, a content of the blocked isocyanate compound having a carboxylic acid group is preferably 50% by mass or more, more preferably 80% by mass or more, and particularly preferably 90% by mass to 100% by mass with respect to a total mass of the blocked isocyanate compound included in the photosensitive resin composition.

<Binder Polymer>

The photosensitive resin composition according to the disclosure includes a binder polymer.

The binder polymer is preferably an alkali soluble resin.

The binder polymer is not particularly limited, but from a viewpoint of developability, the binder polymer is preferably a binder polymer having an acid value of 60 mgKOH/g or more, more preferably an alkali soluble resin having an acid value of 60 mgKOH/g or more, and particularly preferably a carboxyl group-containing acrylic resin having an acid value of 60 mgKOH/g or more.

It is assumed that, since the binder polymer has an acid value, a compound capable of reacting with an acid can be thermally crosslinked with the binder polymer by heating to increase a three-dimensional crosslink density. In addition, it is assumed that a carboxy group of a carboxy group-containing acrylic resin is dehydrated and made hydrophobic to contribute to improvement of wet heat resistance.

The carboxy group-containing acrylic resin having an acid value of 60 mgKOH/g or more (hereinafter, may be referred to as a specific polymer A) is not particularly limited, as long as the acid value condition is satisfied, and a resin can be suitably selected and used from well-known resins.

For example, a binder polymer which is a carboxy group-containing acrylic resin having an acid value of 60 mgKOH/g or more among polymers disclosed in paragraph 0025 of JP2011-095716A, a carboxy group-containing acrylic resin having an acid value of 60 mgKOH/g or more among polymers disclosed in paragraphs 0033 to 0052 of JP2010-237589A, and the like can be preferably used as the specific polymer A in the embodiment.

Here, the (meth)acrylic resin indicates to a resin containing at least one of a constitutional unit derived from (meth)acrylic acid or a constitutional unit derived from a (meth)acrylic acid ester.

A total ratio of the constitutional unit derived from (meth)acrylic acid and the constitutional unit derived from (meth)acrylic acid ester in the (meth)acrylic resin is preferably 30 mol % or more and more preferably 50 mol % or more.

A range of a copolymerization ratio of the monomer having a carboxy group in the specific polymer A is preferably 5% by mass to 50% by mass, more preferably 5% by mass to 40% by mass, and even more preferably 10% by mass to 30% by mass, with respect to 100% by mass of the specific polymer A.

The specific polymer A may have a reactive group, and as a method for introducing the reactive group into the specific polymer A, a method for causing a reaction of an epoxy compound, blocked isocyanate, isocyanate, a vinyl sulfone compound, an aldehyde compound, a methylol compound, a carboxylic acid anhydride, or the like with a hydroxyl group, a carboxy group, a primary amino group, a secondary amino group, an acetoacetyl group, sulfonic acid, or the like is used.

Among these, the reactive group is preferably a radically polymerizable group, more preferably an ethylenically unsaturated group, and particularly preferably a (meth)acryloxy group.

In addition, the binder polymer, particularly the specific polymer A, preferably has a constitutional unit having an aromatic ring, from a viewpoint of moisture permeability and hardness after curing.

Examples of a monomer forming the constitutional unit having an aromatic ring include styrene, tert-butoxystyrene, methyl styrene, α-methyl styrene, and benzyl (meth)acrylate.

As the constitutional unit having an aromatic ring, it is preferable to contain at least one constitutional unit represented by Formula P-2 which will be described later. The constitutional unit having an aromatic ring is preferably a constitutional unit derived from a styrene compound.

In a case where the binder polymer includes a constitutional unit having an aromatic ring, a content of the constitutional unit having an aromatic ring is preferably 5% by mass to 90% by mass, and more preferably 10% by mass to 70% by mass, even more preferably 15% by mass to 50% by mass, with respect to a total mass of the binder polymer.

In addition, the binder polymer, particularly the specific polymer A, preferably has a constitutional unit having an alicyclic skeleton, from a viewpoint of tackiness and hardness after curing.

Specific examples of the monomer forming the constitutional unit having an alicyclic skeleton include dicyclopentanyl (meth)acrylate, cyclohexyl (meth)acrylate, and isobornyl (meth)acrylate.

Preferred examples of the aliphatic ring included in the constitutional unit having an alicyclic skeleton include a dicyclopentane ring, a cyclohexane ring, an isophorone ring, and a tricyclodecane ring. Among these, a tricyclodecane ring is particularly preferable.

In a case where the binder polymer includes a constitutional unit having an alicyclic skeleton, a content of the constitutional unit having an alicyclic skeleton is preferably 5% by mass to 90% by mass, more preferably 10% by mass to 80% by mass, and even more preferably 20% by mass to 70% by mass, with respect to a total mass of the binder polymer.

In addition, the binder polymer, particularly the specific polymer A, preferably has a constitutional unit having an ethylenically unsaturated group and more preferably has a constitutional unit having an ethylenically unsaturated group in a side chain, from a viewpoint of tackiness and hardness after curing.

In the disclosure, the “main chain” represents a relatively longest binding chain in a molecule of a polymer compound constituting a resin, and the “side chain” represents an atomic group branched from the main chain.

The ethylenically unsaturated group is preferably a (meth)acryl group and more preferably a (meth)acryloxy group.

In a case where the binder polymer includes a constitutional unit having an ethylenically unsaturated group, a content of the constitutional unit having an ethylenically unsaturated group is preferably 5% by mass to 70% by mass, and more preferably 5% by mass to 50% by mass, even more preferably 10% by mass to 40% by mass, with respect to a total mass of the binder polymer.

The acid value of the binder polymer used in the disclosure is preferably 60 mgKOH/g or more, and more preferably 60 mgKOH/g to 200 mgKOH/g, even more preferably 60 mgKOH/g to 150 mgKOH/g, and particularly preferably 60 mgKOH/g to 130 mgKOH/g.

In the specification, the acid value refers to a value measured according to the method disclosed in JIS K0070 (1992).

Since the binder polymer includes a binder polymer having an acid value of 60 mgKOH/g or more, it is possible to increase interlaminar adhesion between the photosensitive layer and a second resin layer which will be described later, in addition to the above-mentioned advantages, because the second resin layer includes an acrylic resin having an acid group.

A weight-average molecular weight of the specific polymer A is preferably 5,000 or more and more preferably 10,000 to 100,000.

In addition, as the binder polymer, any film-forming resin can be suitably selected and used according to the purpose, in addition to the specific polymer. From a viewpoint of using the transfer film as the electrode protective film of the capacitive input device, a film having good surface hardness and heat resistance is preferable, an alkali soluble resin is more preferable, and among the alkali soluble resins, a well-known photosensitive siloxane resin material can be preferably used.

The binder polymer used in the disclosure preferably includes a polymer containing a constitutional unit having a carboxylic acid anhydride structure (hereinafter, also referred to as a specific polymer B). By including the specific polymer B, the developability and the hardness after curing are more excellent.

The carboxylic acid anhydride structure may be either a chain carboxylic acid anhydride structure or a cyclic carboxylic acid anhydride structure, and is preferably a cyclic carboxylic acid anhydride structure.

The ring of the cyclic carboxylic acid anhydride structure is preferably a 5- to 7-membered ring, more preferably a 5-membered ring or a 6-membered ring, and even more preferably a 5-membered ring.

In addition, the cyclic carboxylic acid anhydride structure may be condensed or bonded with another ring structure to form a polycyclic structure, but preferably does not form a polycyclic structure.

In a case where another ring structure is condensed or bonded to the cyclic carboxylic acid anhydride structure to form a polycyclic structure, the polycyclic structure is preferably a bicyclo structure or a spiro structure.

In the polycyclic structure, the number of other ring structures condensed or bonded to the cyclic carboxylic acid anhydride structure is preferably 1 to 5, and more preferably 1 to 3.

Examples of the other ring structure include a cyclic hydrocarbon group having 3 to 20 carbon atoms and a heterocyclic group having 3 to 20 carbon atoms.

The heterocyclic group is not particularly limited, and examples thereof include an aliphatic heterocyclic group and an aromatic heterocyclic group.

In addition, the heterocyclic group is preferably a 5-membered ring or a 6-membered ring, and particularly preferably a 5-membered ring.

Further, as the heterocyclic group, a heterocyclic group containing at least one oxygen atom (for example, an oxolane ring, an oxane ring, or a dioxane ring) is preferable.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or via a divalent linking group.

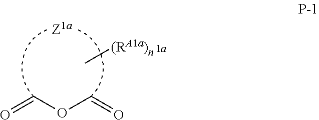

In Formula P-1, R^{A1a} represents a substituent and n1a R^{Ala}'s may be the same or different.

Z^{1a} represents a divalent group forming a ring containing —C(═O)—O—C(═O)—. n^{1a} represents an integer of 0 or more.

As a substituent represented by R^{A1a}, the same substituent as the substituent which may be included in the carboxylic acid anhydride structure may be used, and the preferable range is also the same.

Z^{1a} is preferably an alkylene group having 2 to 4 carbon atoms, more preferably an alkylene group having 2 or 3 carbon atoms, and particularly preferably an alkylene group having 2 carbon atoms.

In addition, the partial structure represented by Formula P-1 may be condensed or bonded with another ring structure to form a polycyclic structure, but preferably does not form a polycyclic structure.

As the other ring structure here, the same ring structure as the other ring structure described above which may be condensed or bonded to the carboxylic acid anhydride structure may be used, and the preferable range is also the same.

n^{1a} represents an integer of 0 or more.

In a case where Z^{1a} represents an alkylene group having 2 to 4 carbon atoms, n^{1a} is preferably an integer of 0 to 4, more preferably an integer of 0 to 2, and even more preferably 0.

In a case where n^{1a} represents an integer of 2 or more, a plurality of R^{A1a}'s existing may be the same or different. In addition, the plurality of R^{A1a}'s existing may be bonded to each other to form a ring, but it is preferable that they are not bonded to each other to form a ring.

The constitutional unit having a carboxylic acid anhydride structure is preferably a constitutional unit derived from an unsaturated carboxylic acid anhydride, more preferably a constitutional unit derived from an unsaturated cyclic carboxylic acid anhydride, even more preferably a constitutional unit derived from an unsaturated alicyclic carboxylic acid anhydride, still preferably a constitutional unit derived from maleic anhydride or itaconic anhydride, and particularly preferably a constitutional unit derived from maleic anhydride.

Hereinafter, specific examples of the constitutional unit having a carboxylic acid anhydride structure will be described, but the constitutional unit having a carboxylic acid anhydride structure is not limited to these specific examples.

In the following constitutional units, Rx represents a hydrogen atom, a methyl group, a CH₂OH group, or a CF₃ group, and Me represents a methyl group.

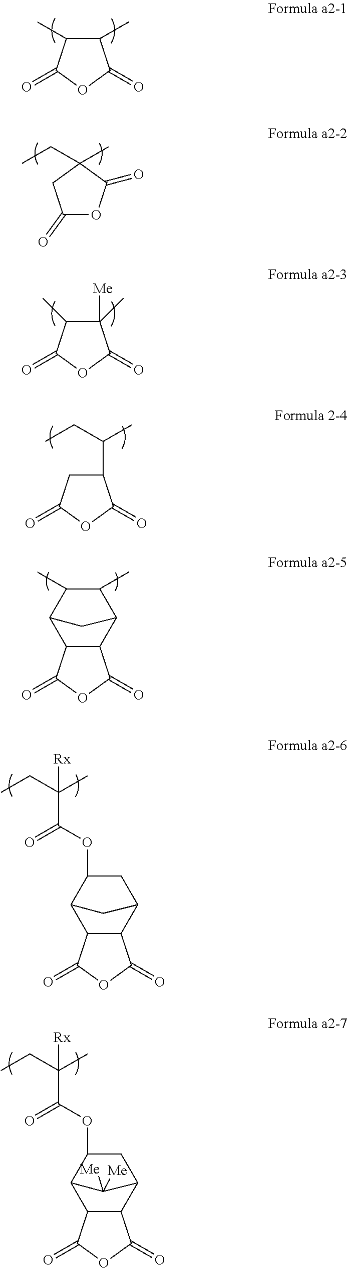

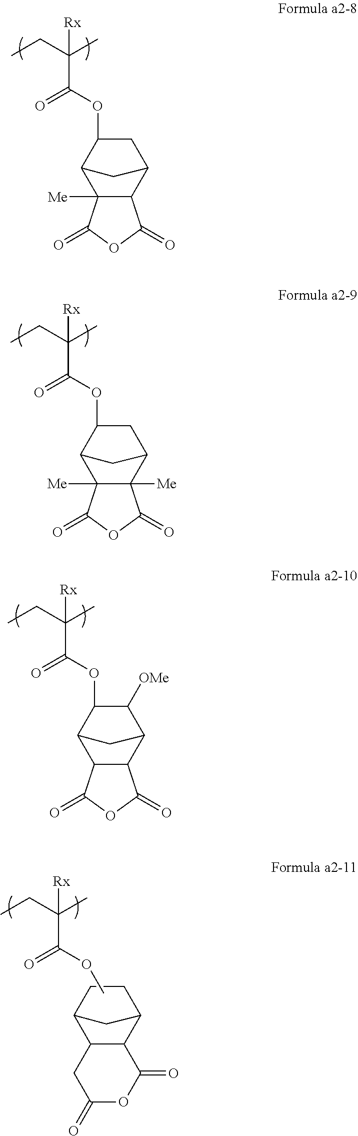

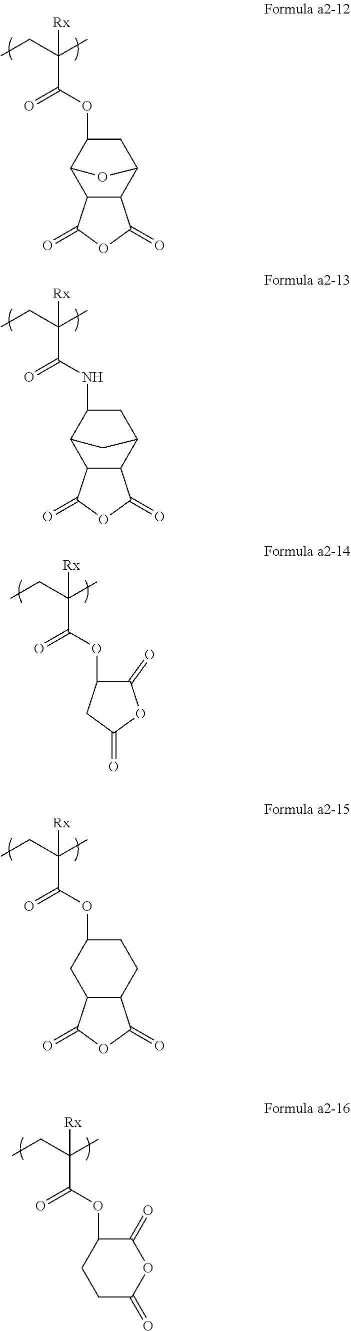

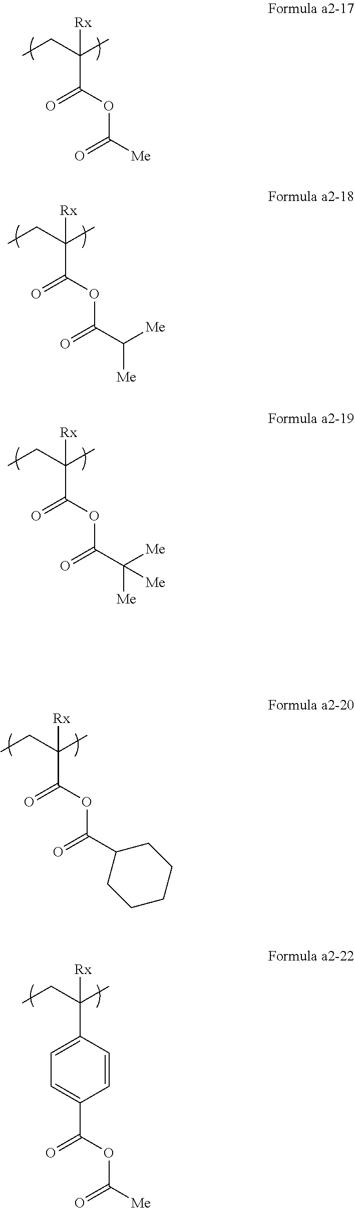

The constitutional unit having a carboxylic acid anhydride structure is preferably at least one of the constitutional units represented by any of Formulae a2-1 to a2-21, and more preferably one of the constitutional units represented by any of Formulae a2-1 to a2-21.

The constitutional unit having a carboxylic acid anhydride structure preferably has at least one of the constitutional unit represented by Formula a2-1 or the constitutional unit represented by Formula a2-2, and more preferably the constitutional unit represented by Formula a2-1, from viewpoints of developability and moisture permeability of the cured film to be obtained.

A content of constitutional unit having a carboxylic acid anhydride structure in the specific polymer B (in the case of two or more kinds, total content thereof. The same applies hereinafter) is preferably 0 mol % to 60 mol %, more preferably 5 mol % to 40 mol %, and even more preferably 10 mol % to 35 mol %, with respect to the total amount of the specific polymer B.

In the disclosure, in a case where the content of the “constitutional unit” is defined by a molar ratio, the “constitutional unit” is synonymous with the “monomer unit”. In addition, in the disclosure, the “monomer unit” may be modified after polymerization by a polymer reaction or the like. The same applies to the followings.

As the specific polymer B, it is preferable to contain at least one constitutional unit represented by Formula P-2. Accordingly, the moisture permeability of the cured film to be obtained is more reduced and the strength is further improved.

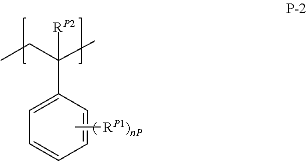

In Formula P-2, R^{P1} represents a hydroxyl group, an alkyl group, an aryl group, an alkoxy group, a carboxy group, or a halogen atom, R^{P2} represents a hydrogen atom, an alkyl group, or an aryl group, and nP represents an integer of 0 to 5. In a case where nP is an integer of 2 or more, two or more existing R^{P1}'s may be the same or different.

R^{P1} is preferably an alkyl group having 1 to 10 carbon atoms, an aryl group having 6 to 12 carbon atoms, an alkoxy group having 1 to 10 carbon atoms, a carboxy group, an F atom, a Cl atom, a Br atom, or an I atom, and more preferably an alkyl group having 1 to 4 carbon atoms, a phenyl group, an alkoxy group having 1 to 4 carbon atoms, a Cl atom, or a Br atom.

R^{P2} is preferably a hydrogen atom, an alkyl group having 1 to 10 carbon atoms, or an aryl group having 6 to 12 carbon atoms, more preferably a hydrogen atom or an alkyl group having 1 to 4 carbon atoms, even more preferably a hydrogen atom, a methyl group, or an ethyl group, and particularly preferably a hydrogen atom.

nP is preferably an integer of 0 to 3, more preferably 0 or 1, and further preferably 0.

A constitutional unit represented by formula P-2 is preferably a constitutional unit derived from a styrene compound.

Examples of the styrene compound include styrene, p-methylstyrene, α-methylstyrene, α, p-dimethylstyrene, p-ethylstyrene, p-t-butylstyrene, and 1,1-diphenylethylene, styrene or α-methylstyrene is preferable, and styrene is particularly preferable.

The styrene compound for forming the constitutional unit represented by Formula P-2 may be only one or two or more kinds thereof.

In a case where the specific polymer B includes the constitutional unit represented by Formula P-2, a content of the constitutional units represented by Formula P-2 in the specific polymer B (in the case of two or more kinds, total content thereof. The same applies hereinafter) is preferably 5 mol % to 90 mol %, more preferably 30 mol % to 90 mol %, and even more preferably 40 mol % to 90 mol %, with respect to the total amount of the specific polymer B.

The specific polymer B may include at least one constitutional unit other than the constitutional unit having a carboxylic acid anhydride structure and the constitutional unit represented by Formula P-2.

The other constitutional unit preferably does not contain an acid group.

The other constitutional unit is not particularly limited, and a constitutional unit derived from a monofunctional ethylenically unsaturated compound is used.

As the monofunctional ethylenically unsaturated compound, well-known compounds can be used without particular limitation, and examples thereof include a (meth)acrylic acid derivative such as methyl (meth)acrylate, ethyl (meth)acrylate, n-butyl (meth)acrylate, 2-ethylhexyl (meth)acrylate, carbitol (meth)acrylate, cyclohexyl (meth)acrylate, benzyl (meth)acrylate, or epoxy (meth)acrylate; an N-vinyl compound such as N-vinylpyrrolidone or N-vinylcaprolactam; a derivative of an allyl compound such as allyl glycidyl ether; and the like.

A content of the other constitutional units in the specific polymer B (in the case of two or more kinds, total content thereof) is preferably 0 mol % to 90 mol % and more preferably 0 mol % to 70 mol %, with respect to the total amount of the specific polymer B.

A weight-average molecular weight of the binder polymer is not particularly limited, and is preferably more than 3,000, more preferably more than 3,000 and 60,000 or more, and even more preferably 5,000 to 50,000.

The binder polymer may be used alone or in combination of two or more kinds thereof.

A content of the binder polymer is preferably 10% by mass to 90% by mass, more preferably 20% by mass to 80% by mass, and even more preferably 30% by mass to 70% by mass, with respect to the total solid content of the photosensitive resin composition, from viewpoints of hardness of the cured film to be obtained and handleability of the transfer film.

<Ethylenically Unsaturated Compound Not Having Blocked Isocyanate Group>

The photosensitive resin composition according to the disclosure includes an ethylenically unsaturated compound not having a blocked isocyanate group (hereinafter, also simply referred to as an “ethylenically unsaturated compound”).

The ethylenically unsaturated compound is a component that contributes to photosensitivity (that is, photocuring properties) and strength of the cured film to be obtained.

The ethylenically unsaturated compound is a compound having one or more ethylenically unsaturated groups.

The photosensitive resin composition preferably includes a di- or higher functional ethylenically unsaturated compound as the ethylenically unsaturated compound.

Here, the di- or higher functional ethylenically unsaturated compound refers to a compound having two or more ethylenically unsaturated groups in one molecule.

As the ethylenically unsaturated group, a (meth)acryloyl group is more preferable.

As the ethylenically unsaturated compound, a (meth)acrylate compound is preferable.

From a viewpoint of curability after curing, the photosensitive resin composition particularly preferably includes a difunctional ethylenically unsaturated compound (preferably a difunctional (meth)acrylate compound) and a tri- or higher functional ethylenically unsaturated compound (preferably a tri- or higher functional (meth)acrylate compound).

The difunctional ethylenically unsaturated compound is not particularly limited and can be suitably selected from well-known compounds.

Examples of the difunctional ethylenically unsaturated compound include tricyclodecane dimethanol di(meth)acrylate, 1,9-nonanediol di(meth)acrylate, and 1,6-hexanediol di(meth)acrylate.

Specific examples of the difunctional ethylenically unsaturated compound include tricyclodecane dimethanol diacrylate (A-DCP, manufactured by Shin-Nakamura Chemical Co., Ltd.), tricyclodecane dimethanol dimethacrylate (DCP, manufactured by Shin-Nakamura Chemical Co., Ltd.), 1,9-nonanediol diacrylate (A-NOD-N, manufactured by Shin-Nakamura Chemical Co., Ltd.), 1,6-hexanediol diacrylate (A-HD-N, manufactured by Shin-Nakamura Chemical Co., Ltd.), and polytetramethylene glycol #650 diacrylate (A-PTMG-65, manufactured by Shin-Nakamura Chemical Co., Ltd.).

The tri- or higher functional ethylenically unsaturated compound is not particularly limited and can be suitably selected from well-known compounds.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the ethylenically unsaturated compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD RP-1040 manufactured by Nippon Kayaku Co., Ltd., ATM-35E, A-9300 manufactured by Shin-Nakamura Chemical Co., Ltd., EBECRYL (registered trademark) 135 manufactured by Daicel-Allnex Ltd., or the like), and ethoxylated glycerin triacrylate (A-GLY-9E manufactured by Shin-Nakamura Chemical Co., Ltd.).

As the ethylenically unsaturated compound, a urethane (meth)acrylate compound (preferably tri- or higher functional urethane (meth)acrylate compound) is also used.

Examples of the tri- or higher functional urethane (meth)acrylate compound include 8UX-015A (manufactured by Taisei Fine Chemical Co., Ltd.), UA-32P (manufactured by Shin-Nakamura Chemical Co., Ltd.), and UA-1100H (manufactured by Shin-Nakamura Chemical Co., Ltd.).

In addition, the ethylenically unsaturated compound preferably includes an ethylenically unsaturated compound having an acid group, from a viewpoint of improving developability.

Examples of the acid group include a phosphoric acid group, a sulfonic acid group, and a carboxy group, and a carboxy group is preferable.

Examples of the ethylenically unsaturated compound including the acid group include a tri- or tetra-functional ethylenically unsaturated compound including the acid group (component obtained by introducing a carboxy group to pentaerythritol tri- and tetra-acrylate (PETA) skeleton (acid value=80 mgKOH/g to 120 mgKOH/g)), and a penta- to hexa-functional ethylenically unsaturated compound including the acid group (component obtained by introducing a carboxy group to dipentaerythritol penta- and hexa-acrylate (DPHA) skeleton (acid value=25 mgKOH/g to 70 mgKOH/g)).

The tri- or higher functional Ethylenically unsaturated compound including the acid group may be used in combination with the difunctional ethylenically unsaturated compound including the acid group, as necessary.

As the ethylenically unsaturated compound including the acid group, at least one kind selected from the group consisting of di- or higher functional ethylenically unsaturated compound including carboxy group and a carboxylic acid anhydride thereof is preferable. This improves developability and hardness of the cured film.

The di- or higher functional ethylenically unsaturated compound including a carboxy group is not particularly limited and can be suitably selected from well-known compounds.

For example, as the di- or higher functional ethylenically unsaturated compound including a carboxy group, ARONIX (registered trademark) TO-2349 (manufactured by Toagosei Co., Ltd.), ARONIX M-520 (manufactured by Toagosei Co., Ltd.), or ARONIX M-510 (manufactured by Toagosei Co., Ltd.) can be preferably used.

The ethylenically unsaturated compound including the acid group is also preferably a polymerizable compound including an acid group disclosed in paragraphs 0025 to 0030 of JP2004-239942A. The content of this publication is incorporated in this specification.

A weight-average molecular weight (Mw) of the ethylenically unsaturated compound used in the disclosure is preferably 200 to 3,000, more preferably 250 to 2,600, even more preferably 280 to 2,200, and particularly preferably 300 to 2, 200.

In addition, a ratio of the content of the ethylenically unsaturated compound having a molecular weight of 300 or less, among all of the ethylenically unsaturated compound included in the photosensitive resin composition is preferably 30% by mass or less, more preferably 25% by mass or less, and even more preferably 20% by mass or less, with respect to all of the ethylenically unsaturated compounds included in the photosensitive resin composition.

The ethylenically unsaturated compound may be used alone or in combination of two or more thereof.

The content of the ethylenically unsaturated compound is preferably 1% by mass to 70% by mass, more preferably 10% by mass to 70% by mass, even more preferably 20% by mass to 60% by mass, and particularly preferably 20% by mass to 50% by mass, with respect to a total solid content of the photosensitive resin composition.

In addition, in a case where the photosensitive resin composition includes a difunctional ethylenically unsaturated compound and a tri- or higher functional ethylenically unsaturated compound, the content of the difunctional ethylenically unsaturated compound is preferably 10% by mass to 90% by mass, more preferably 20% by mass to 85% by mass, and even more preferably 30% by mass to 80% by mass, with respect to all of the ethylenically unsaturated compounds included in the photosensitive resin composition.

In this case, the content of the tri- or higher functional ethylenically unsaturated compound is preferably 10% by mass to 90% by mass, more preferably 15% by mass to 80% by mass, and even more preferably 20% by mass to 70% by mass, with respect to all of the ethylenically unsaturated compounds included in the photosensitive resin composition.

In this case, the content of the di- or higher functional ethylenically unsaturated compound is preferably 40% by mass or more and less than 100% by mass, more preferably 40% by mass to 90% by mass, even more preferably 50% by mass to 80% by mass, and particularly preferably 50% by mass to 70% by mass, with respect to a total content of the difunctional ethylenically unsaturated compound and the tri- or higher functional ethylenically unsaturated compound.

In addition, in a case where the photosensitive resin composition includes a di- or higher functional ethylenically unsaturated compound, the photosensitive resin composition may further include a monofunctional ethylenically unsaturated compound.

Further, in a case where the photosensitive resin composition includes a di- or higher functional ethylenically unsaturated compound, the di- or higher functional ethylenically unsaturated compound is preferably the main component in the ethylenically unsaturated compound contained in the photosensitive resin composition.

Specifically, in a case where the photosensitive resin composition includes di- or higher functional ethylenically unsaturated compound, the content of the di- or higher functional ethylenically unsaturated compound is preferably 40% by mass to 100% by mass, more preferably 50% by mass to 100% by mass, and particularly preferably 60% by mass to 100% by mass with respect to a total content of the ethylenically unsaturated compound included in the photosensitive resin composition.

In a case where the photosensitive resin composition includes the ethylenically unsaturated compound including an acid group (preferably, di- or higher functional ethylenically unsaturated compound including a carboxy group or a carboxylic acid anhydride thereof), the content of the ethylenically unsaturated compound including the acid group is preferably 1% by mass to 50% by mass, more preferably 1% by mass to 20% by mass, and even more preferably 1% by mass to 10% by mass, with respect to the total solid content of the photosensitive resin composition.

<Photopolymerization Initiator>

The photosensitive resin composition according to the disclosure includes a photopolymerization initiator.

The photopolymerization initiator is not particularly limited and a well-known photopolymerization initiator can be used.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, an “α-aminoalkylphenone-based photopolymerization initiator”), a photopolymerization initiator having an α-hydroxyalkylphenone structure (hereinafter also referred to as an “α-hydroxyalkylphenone-based photopolymerization initiator”), a photopolymerization initiator having an acylphosphine oxide structure. (hereinafter, also referred to as an “acylphosphine oxide-based photopolymerization initiator”), and a photopolymerization initiator having an N-phenylglycine structure (hereinafter, “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs 0031 to 0042 of JP2011-095716A and paragraphs 0064 to 0081 of JP2015-014783A may be used.

Examples of a commercially available product of the photopolymerization initiator include 1-[4-(phenylthio)-1,2-octanedione-2-(O-benzoyloxime) (product name: IRGACURE (registered trademark) OXE-01, manufactured by BASF Japan Ltd.), 1-[9-ethyl-6-(2-methylbenzoyl)-9H-carbazole-3-yl] ethanone-1-(O-acetyloxime) (product name: IRGACURE OXE-02, manufactured by BASF Japan Ltd.), 2-(dimethylamino)-2-[(4-methylphenyl)methyl]-1-[4-(4-morpholinyl)phenyl]-1-butanone (product name: IRGACURE 379EG; manufactured by BASF Japan Ltd.), 2-methyl-1-(4-methylthiophenyl)-2-morpholinopropan-1-one (product name: IRGACURE 907, manufactured by BASF Japan Ltd.), 2-hydroxy-1-{4-[4-(2-hydroxy-2-methyl-propionyl)-benzyl]phenyl}-2-methyl-propan-1-one (product name: IRGACURE 127, manufactured by BASF Japan Ltd.), 2-benzyl-2-dimethylamino-1-(4-morpholinophenyl)-butanone-1 (product name: IRGACURE 369, manufactured by BASF Japan Ltd.), 2-hydroxy-2-methyl-1-phenyl-propan-1-one (product name: IRGACURE 1173, manufactured by BASF Japan Ltd.), 1-hydroxy cyclohexyl phenyl ketone (product name: IRGACURE 184, manufactured by BASF Japan Ltd.), 2,2-dimethoxy-1,2-diphenylethan-1-one (product name: IRGACURE 651, manufactured by BASF Japan Ltd.), and a product name of an oxime ester type (product name: Lunar 6, manufactured by DKSH Management Ltd.).

The photopolymerization initiator may be used alone or in combination of two or more thereof.

The content of the photopolymerization initiator is not particularly limited and is preferably 0.1% by mass or more, more preferably 0.2% by mass or more, and even more preferably 0.3% by mass or more with respect to the total solid content of the photosensitive resin composition.

In addition, the content of the photopolymerization initiator is preferably equal to or smaller than 10% by mass and more preferably equal to or smaller than 5% by mass, with respect to the total solid content of the photosensitive resin composition.

<Heterocyclic Compound>

The photosensitive resin composition according to the disclosure preferably further includes a heterocyclic compound, from viewpoints of discoloration prevention properties of the metal wiring in contact and linearity of an obtained pattern.

Examples of hetero atom included in the heterocyclic compound include an oxygen atom, a nitrogen atom, and a sulfur atom. Among them, from a viewpoint of discoloration prevention properties of the metal wiring in contact and linearity of the obtained pattern, it is preferable to have at least one atom selected from the group consisting of a nitrogen atom, a sulfur atom, and an oxygen atom as the hetero atom, and it is more preferable to have at least a nitrogen atom as the hetero atom.

The heterocyclic compound preferably has a nitrogen atom, from a viewpoint of discoloration prevention properties of metal in contact, and linearity of the obtained pattern. The heterocyclic ring in the heterocyclic compound more preferably includes a nitrogen atom, the heterocyclic ring in the heterocyclic compound is even more preferably a 5-membered ring containing a nitrogen atom, and the heterocyclic ring in the heterocyclic compound is particularly preferably a 5-membered ring containing a nitrogen atom, a sulfur atom, and an oxygen atom.

In addition, the heterocyclic ring of the heterocyclic compound is preferably a 5-membered ring or a 6-membered ring and more preferably a 5-membered ring, from a viewpoint of discoloration prevention properties of metal wiring in contact and linearity of the obtained pattern.

The heterocyclic compound is preferably a heterocyclic compound having a mercapto group (thiol group) and more preferably a heterocyclic compound in which a mercapto group is directly bonded to the heterocyclic ring, from a viewpoint of discoloration prevention properties of metal wiring in contact and linearity of the obtained pattern.

In addition, in a case where the heterocyclic compound has a mercapto group, the number of mercapto groups in the heterocyclic compound is not particularly limited, but from a viewpoint of discoloration prevention properties of metal wiring in contact and linearity of the obtained pattern, it is preferably 1 to 6, more preferably 1 to 4, even more preferably 1 or 2, and particularly preferably 1.

Examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound.

Among them, a triazole compound, a benzotriazole compound, a tetrazole compound, a thiadiazole compound, a triazine compound, a rhodanine compound, a thiazole compounds, a benzimidazole compounds, or a benzoxazole compound is preferable, a triazole compounds, a benzotriazole compound, a tetrazole compound, a thiadiazole compound, a thiazole compound, a benzothiazole compound, a benzimidazole compound, or a benzoxazole compound is more preferable, and a thiadiazole compound, a thiazole compound, a benzothiazole compound, or a benzoxazole compound is particularly preferable.

The heterocyclic compound is not particularly limited, but it is preferably a compound represented by any one of Formulae H1 to H13, from viewpoints of adhesion, discoloration prevention properties of metal wiring in contact, and linearity of the obtained pattern.

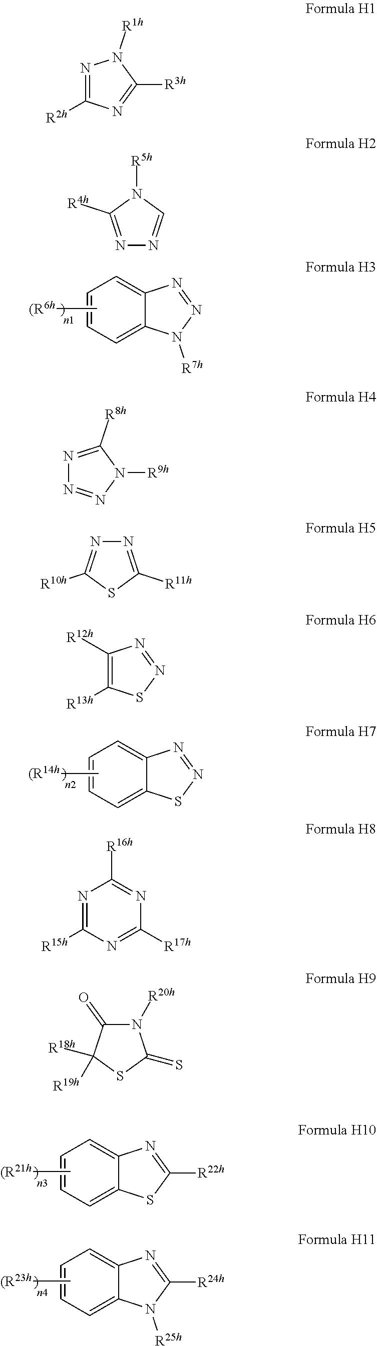

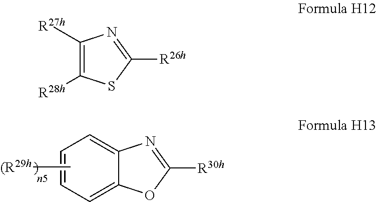

In Formulae H1 to H13, R^{1h}, R^{5h}, R^{7h}, R^{9h}, R^{20h}, and Rash each independently represent a hydrogen atom, an alkyl group, an aryl group, a heteroaryl group, or an amino group, R^{2h} to R^{4h}, R^{8h}, R^{10h} to R^{13h}, R^{15h} to R^{18h}, R^{22h}, R^{24h}, R^{26h} to R^{28h}, and R^{30h} each independently represent a hydrogen atom, an alkyl group, an aryl group, a heteroaryl group, an amino group, an alkylamino group, an arylamino group, a mercapto group, an alkylthio group, or an arylthio group, R^{6h}, R^{14h}, R^{21h}, R^{23h}, and R^{29h} each independently represent a halogen atom, an alkyl group, an aryl group, a heteroaryl group, an amino group, an alkylamino group, an arylamino group, a mercapto group, an alkylthio group, an arylthio group, a carboxy group, a hydroxy group, an alkoxy group, or an aryloxy group, R^{19h} represents a hydrogen atom, an alkyl group, an aryl group, or a heteroaryl group, n1 to n5 each independently represents an integer of 0 to 4.

The compound represented by Formula H1 or Formula H2 is a triazole compound, the compound represented by Formula H3 is a benzotriazole compound, the compound represented by Formula H4 is a tetrazole compound, the compound represented by Formula H5 to Formula H7 is a thiadiazole compound, the compound represented by Formula H8 is a triazine compound, the compound represented by Formula H9 is a rhodanine compound, the compound represented by Formula H10 is a benzothiazole compound, the compound represented by Formula H11 is a benzimidazole compound, the compound represented by Formula H12 is a thiazole compound, and the compound represented by the Formula H13 is a benzoxazole compound.

R^{1h}, R^{7h}, R^{9h}, R^{20h}, and R^{25h} are each independently preferably a hydrogen atom, an alkyl group, an aryl group, or a heteroaryl group, more preferably a hydrogen atom or an alkyl group, and particularly preferably a hydrogen atom.

R^{5h} is preferably a hydrogen atom, an alkyl group, or an amino group and more preferably a hydrogen atom or an amino group.

R^{2h} to R^{4h}, R^{8h}, R^{10h} to R^{13h}, R^{15h} to R^{18h}, R^{22h}, R^{24h}, R^{26h} to R^{28h}, and R^{30h} are each independently preferably a hydrogen atom, an alkyl group, an aryl group, a heteroaryl group, an amino group, a mercapto group, or an alkylthio group, and more preferably a hydrogen atom, an amino group, a mercapto group, or an alkylthio group.

R^{15h} to R^{17h} are each independently preferably a hydrogen atom, an alkyl group, an aryl group, a heteroaryl group, an amino group, a mercapto group, or an alkylthio group, more preferably an amino group or a heteroaryl group, and particularly preferably an amino group or a pyridyl group.

In addition, from a viewpoint of synthesis, R¹⁵ to R¹⁷ are preferably the same group.

R^{18h} is preferably a hydrogen atom, an alkyl group, an aryl group, a heteroaryl group, an amino group, a mercapto group, or an alkylthio group, more preferably a hydrogen atom, an amino group, a mercapto group, or an alkylthio group, and even more preferably a hydrogen atom.

R^{6h}, R^{14h}, R^{21h}, R^{23h}, and R^{29h} are each independently preferably an alkyl group, an aryl group, a heteroaryl group, an amino group, an alkylamino group, an arylamino group, a mercapto group, an alkylthio group, arylthio group, a carboxy group, a hydroxy group, an alkoxy group, or an aryloxy group, and more preferably an alkyl group, an aryl group, a heteroaryl group, an amino group, a mercapto group, an alkylthio group, an arylthio group, or a carboxy group.

In addition, in R^{6h}, R^{14h}, R^{21h}, R^{23h}, and R^{29h}, a hydrogen atom at any position on the benzene ring in each formula can be substituted and bonded.

R^{19h} preferably a hydrogen atom or an alkyl group and more preferably a hydrogen atom.

n1 to n5 are each independently preferably an integer of 0 to 2, more preferably 0 or 1, and particularly preferably 0.

From a viewpoint of adhesion properties, the heterocyclic compound is preferably a compound represented by any of Formulae H1, H2, and H4 to H13, more preferably a compound represented by any of Formulae H4 to H13, even more preferably a compound represented by any of Formulae H5 to H7, H10 and H13, particularly preferably a compound represented by any of Formulae H5 to H7 and H13.

In addition, from a viewpoint of discoloration prevention properties metal wiring in contact and linearity of the obtained pattern, the heterocyclic compound is preferably a compound represented by any of Formulae H5 to H7 and H13, more preferably a compound represented by any of Formula H5, Formula H6, and Formula H13, even more preferably a compound represented by Formula H6 or a compound represented by Formula H13, and particularly preferably a compound represented by Formula H13.

As the heterocyclic compound, specifically, the following compounds can be preferably exemplified.

The following compounds can be exemplified as a triazole compound and a benzotriazole compound.

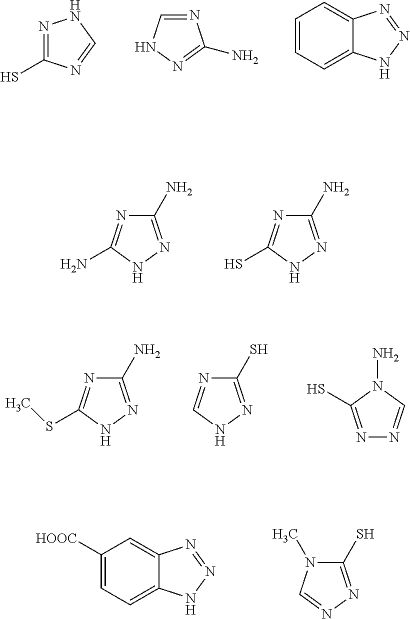

The following compounds can be exemplified as a tetrazole compound.

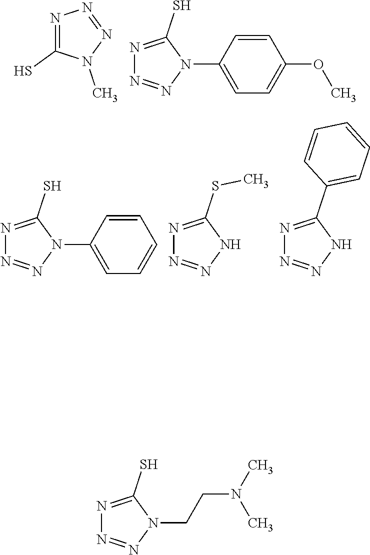

The following compounds can be exemplified as a thiadiazole compound.

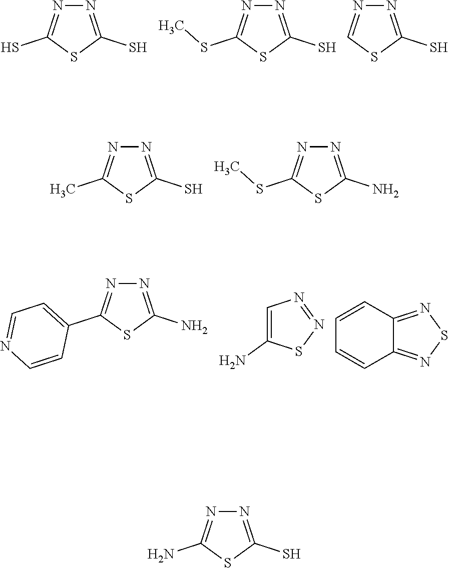

The following compounds can be exemplified as a triazine compound.

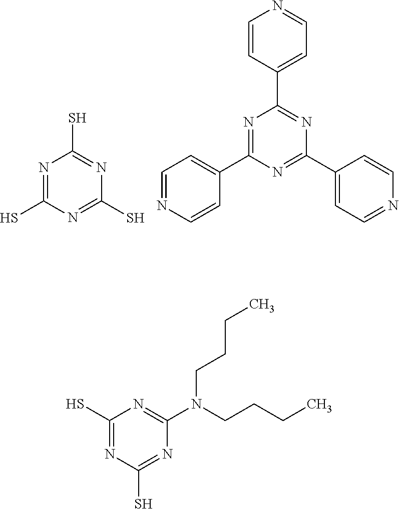

The following compounds can be exemplified as a rhodanine compound.

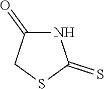

The following compounds are exemplified as a thiazole compound.

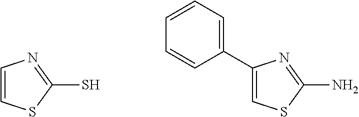 [SMILES: Sc1nccs1 ; Nc1nc(-c2ccccc2)cs1]

The following compounds are exemplified as a benzothiazole compound.

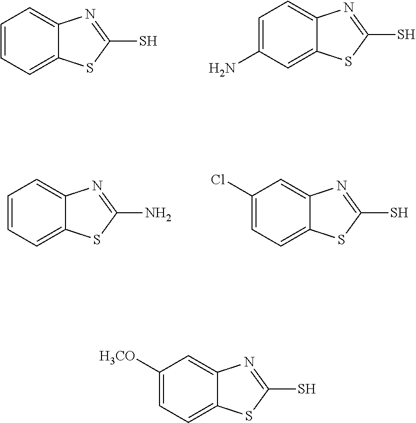 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

The following compounds can be exemplified as a benzimidazole compound.

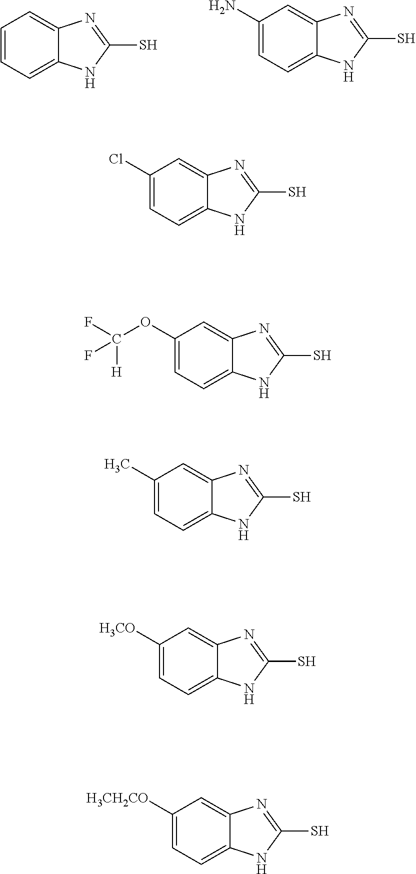

The following compounds can be exemplified as a benzoxazole compound.

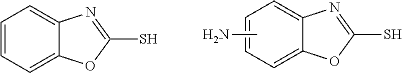

The photosensitive resin composition may contain one kind or two or more kinds of the heterocyclic compound described above.

The content of the heterocyclic compound is not particularly limited, but from a viewpoint of the discoloration prevention properties metal wiring in contact and the linearity of the obtained pattern, is preferably 0.01% by mass to 20% by mass, more preferably 0.1% to 10% by mass, even more preferably 0.5% to 8% by mass, particularly preferably 1% to 5% by mass, with respect to the total solid content of the photosensitive resin composition. In a case where the content thereof is in the above range, the obtained cured product is excellent in hardness and corrosion resistance to metal wiring, and the obtained cured product is excellent in transparency.

<Thiol Compound>

The photosensitive resin composition according to the disclosure preferably further includes a thiol compound.

As the thiol compound, a monofunctional thiol compound or a polyfunctional thiol compound is preferably used. Among them, from a viewpoint of hardness after curing, the thiol compound is preferably a di- or higher functional thiol compound (polyfunctional thiol compound) and more preferably a polyfunctional thiol compound.

In the disclosure, the polyfunctional thiol compound refers to a compound having two or more mercapto groups (thiol groups) in a molecule. The polyfunctional thiol compound is preferably a low-molecular-weight compound having a molecular weight of 100 or more, and specifically, the molecular weight thereof is more preferably 100 to 1,500 and even more preferably 150 to 1,000.

The number of functional groups of the polyfunctional thiol compound is preferably 2 to 10, more preferably 2 to 8, and even more preferably 2 to 6, from a viewpoint of hardness after curing.

In addition, the polyfunctional thiol compound is preferably an aliphatic polyfunctional thiol compound, from viewpoints of tackiness and bending resistance and hardness after curing.

Further, the thiol compound is more preferably a secondary thiol compound, from a viewpoint of bending resistance and hardness after curing.

Specific examples of the polyfunctional thiol compound include trimethylolpropane tris (3-mercaptobutyrate), 1,4-bis (3-mercaptobutyryloxy) butane, pentaerythritol tetrakis (3-mercaptobutyrate), 1,3,5-tris (3-mercaptobutyryloxyethyl)-1,3,5-triazine-2,4,6 (1H, 3H, 5H)-trione, trimethylolethanetris (3-mercaptobutyrate), tris [(3-mercaptopropionyloxy) ethyl] isocyanurate, trimethylolpropane tris (3-mercaptopropionate), pentaerythritol tetrakis (3-mercaptopropionate), tetraethylene glycol bis (3-mercaptopropionate), dipentaerythritol hexakis (3-mercaptopropionate), ethylene glycol bisthiopropionate, 1,4-bis (3-mercaptobutyryloxy) butane, 1,2-benzenedithiol, 1,3-benzenedithiol, 1,2-ethanedithiol, 1,3-propanedithiol, 1,6-hexamethylenedithiol, 2,2′-(ethylenedithio) diethanethiol, meso-2,3-dimercaptosuccinic acid, p-xylylenedithiol, m-xylylenedithiol, and di(mercaptoethyl) ether.

Among these, trimethylolpropane tris (3-mercaptobutyrate), 1,4-bis (3-mercaptobutyryloxy) butane, pentaerythritol tetrakis (3-mercaptobutyrate), 1,3,5-tris (3-mercaptobutyryloxyethyl)-1,3,5-triazine-2,4,6 (1H, 3H, 5H)-trione, trimethylolethanetris (3-mercaptobutyrate), tris [(3-mercaptopropionyloxy) ethyl] isocyanurate, trimethylolpropane tris (3-mercaptopropionate), pentaerythritol tetrakis (3-mercaptopropionate), tetraethylene glycol bis (3-mercaptopropionate), and dipentaerythritol hexakis (3-mercaptopropionate) are preferable.

As the monofunctional thiol compound, both an aliphatic thiol compound and an aromatic thiol compound can be used.

Specific examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

Examples of the monofunctional aromatic thiol compound include benzenethiol, toluenethiol, and xylenethiol.

The thiol compound is preferably a thiol compound having an ester bond and more preferably includes a compound represented by Formula 1, from a viewpoint of tackiness, bending resistance and hardness after curing.

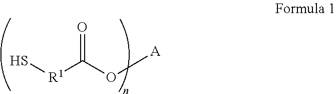

In Formula 1, n represents an integer of 1 to 6, A represents an n-valent organic group having 1 to 15 carbon atoms or a group represented by Formula 2, and R¹'s each independently represent a divalent organic group having 1 to 15 carbon atoms.

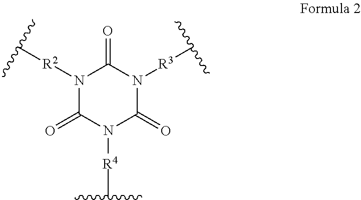

In Formula 2, R² to R⁴ each independently represent a divalent organic group having 1 to 15 carbon atoms, and wavy line parts represent bonding positions to an oxygen atom in Formula 1.

From a viewpoint of hardness after curing, n in Formula 1 is preferably an integer of 2 to 6.

A in Formula 1 is preferably an n-valent aliphatic group having 1 to 15 carbon atoms or a group represented by Formula 2, more preferably an n-valent aliphatic group having 4 to 15 carbon atoms or a group represented by Formula 2, even more preferably an n-valent aliphatic group having 5 to 10 carbon atoms or a group represented by Formula 2, and particularly preferably a group represented by Formula 2, from a viewpoint of tackiness, and bending resistance and hardness after curing.

In addition, A in Formula 1 is preferably an n-valent group consisting of a hydrogen atom and a carbon atom or an n-valent group consisting of a hydrogen atom, a carbon atom, and an oxygen atom, more preferably an n-valent group consisting of a hydrogen atom and a carbon atom, and particularly preferably an n-valent aliphatic hydrocarbon group, from a viewpoint of tackiness, bending resistance and hardness after curing.

R¹'s in Formula 1 are each independently preferably an alkylene group having 1 to 15 carbon atoms, more preferably an alkylene group having 2 to 4 carbon atoms, even more preferably an alkylene group having 3 carbon atoms, and particularly preferably a 1,2-propylene group, from a viewpoint of tackiness, bending resistance and hardness after curing. The alkylene group may be linear or branched.

R² to R⁴ in Formula 2 are each independently preferably an aliphatic group having 2 to 15 carbon atoms, more preferably an alkylene group having 2 to 15 carbon atoms or a polyalkyleneoxyalkyl group having 3 to 15 carbon atoms, even more preferably an alkylene group having 2 to 15 carbon atoms, and particularly preferably an ethylene group, from a viewpoints of tackiness, and bending resistance and hardness after curing.

In addition, as the polyfunctional thiol compound, a compound having two or more groups represented by Formula S-1 is preferable.

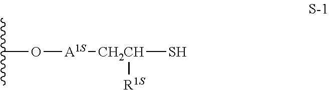

In Formula S-1, R^{1S} represents a hydrogen atom or an alkyl group, A^{1S} represents —CO— or —CH₂—, and wavy line parts represent bonding positions to another structure.

The polyfunctional thiol compound is preferably a compound having 2 to 6 groups represented by Formula S-1.

The alkyl group of R^{1S} in Formula S-1 is a linear, branched, or cyclic alkyl group, and a range of the number of carbon atoms is preferably 1 to 16 and more preferably 1 to 10. Specific examples of the alkyl group include a methyl group, an ethyl group, a propyl group, an isopropyl group, a butyl group, an isobutyl group, an s-butyl group, a t-butyl group, a pentyl group, a hexyl group, and a 2-ethylhexyl group, and a methyl group, an ethyl group, a propyl group, or an isopropyl group is preferable.

As R^{1S}, a hydrogen atom, a methyl group, an ethyl group, a propyl group, or an isopropyl group is particularly preferable, and a methyl group or an ethyl group is most preferable.

In addition, the polyfunctional thiol compound is particularly preferably a compound represented by Formula S-2 having a plurality of groups represented by Formula S-1.

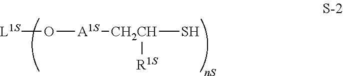

In Formula S-2, R^{1S}'s each independently represent a hydrogen atom or an alkyl group, A^{1S}'s each independently represent —CO— or —CH₂—, L^{1S} represents an nS-valent linking group, and nS represents an integer of 2 to 8. From a viewpoint of synthesis, it is preferable that all R^{1S}'s have the same group, and that all A^{1S}'s have the same group.

R^{1S} in Formula S-2 is same as R^{1S} in Formula S-1 and the preferred range is also the same. nS is preferably an integer of 2 to 6.

Examples of L^{1S}, which is an nS-valent linking group in Formula S-2, include a divalent linking group such as —(CH₂)_{mS}— (mS represents an integer of 2 to 6), a trivalent linking group such as a trimethylolpropane residue, isocyanuric ring having three of —(CH₂)_{pS}-(pS representsan integer of 2 to 6), a tetravalent linking group such as a pentaerythritol residue, and a pentavalent or hexavalent linking group such as a dipentaerythritol residue.

Specific examples of the thiol compound preferably include the following compounds, but are not limited thereto.

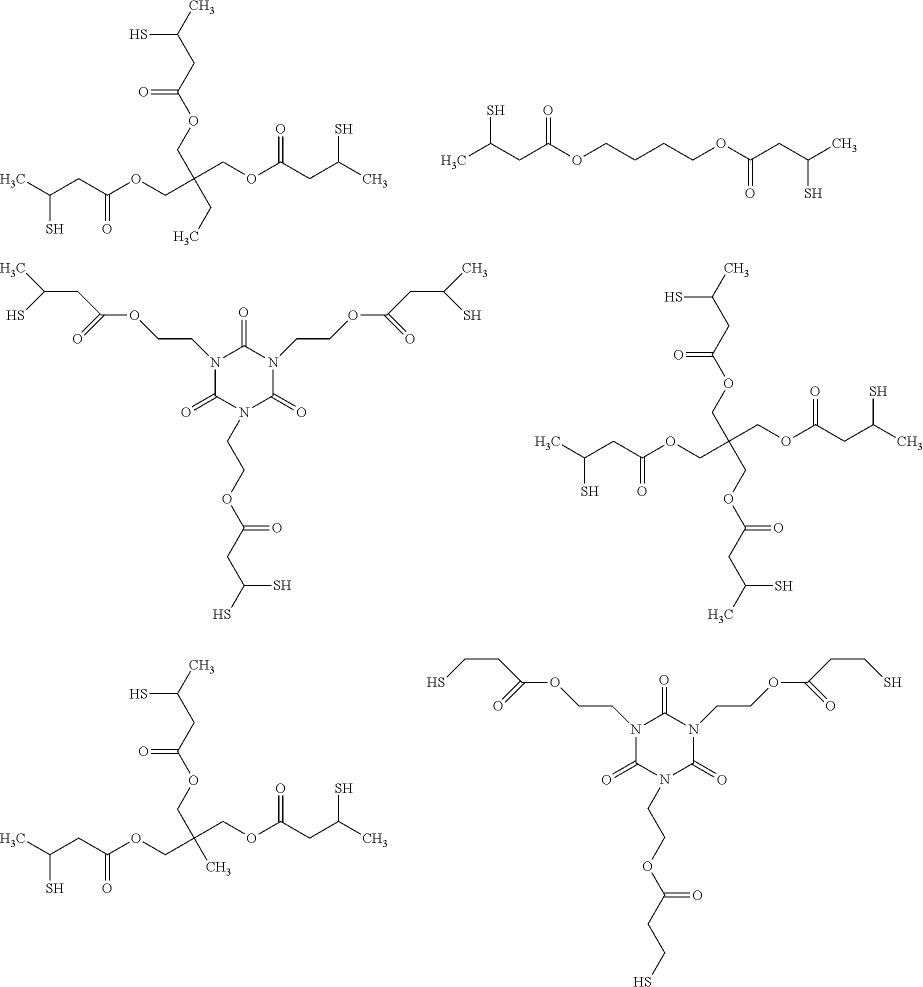 [SMILES: CCC(COC(=O)CC(C)S)(COC(=O)CC(C)S)COC(=O)CC(C)S ; CC(S)CC(=O)OCCCCOC(=O)CC(C)S ; CC(S)CC(=O)OCCn1c(=O)n(CCOC(=O)CC(C)S)c(=O)n(CCOC(=O)CC(S)S)c1=O ; CC(S)CC(=O)OCC(COC(=O)CC(C)S)(COC(=O)CC(C)S)COC(=O)CC(C)S ; CC(S)CC(=O)OCC(C)(COC(=O)CC(C)S)COC(=O)CC(C)S ; O=C(CCS)OCCn1c(=O)n(CCOC(=O)CCS)c(=O)n(CCOC(=O)CCS)c1=O]

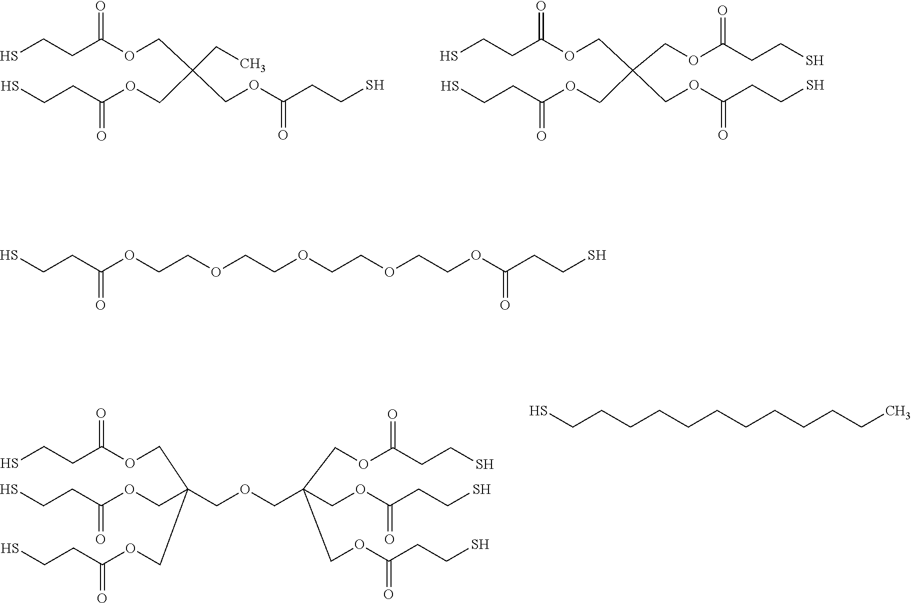 [SMILES: CCC(COC(=O)CCS)(COC(=O)CCS)COC(=O)CCS ; O=C(CCS)OCC(COC(=O)CCS)(COC(=O)CCS)COC(=O)CCS ; O=C(CCS)OCCOCCOCCOCCOC(=O)CCS ; O=C(CCS)OCC(COCC(COC(=O)CCS)(COC(=O)CCS)COC(=O)CCS)(COC(=O)CCS)COC(=O)CCS ; CCCCCCCCCCCCS]

The thiol compounds may be used alone or in combination of two or more thereof.

The content of the thiol compound is preferably 0.1% by mass to 40% by mass, more preferably 0.5% by mass to 30% by mass, and particularly preferably 1% by mass to 25% by mass, with respect to the total solid content of the photosensitive resin composition.

<Surfactant>

The photosensitive resin composition according to the disclosure may include a surfactant.

As the surfactant, for example, surfactants disclosed in paragraph 0017 of JP4502784B and paragraphs 0060 to 0071 of JP2009-237362A, well-known fluorine-based surfactants, and the like can be used.

As the surfactant, a fluorine-based surfactant is preferable.

As a commercially available fluorine-based surfactant, MEGAFACE (registered trademark) F551 (manufactured by DIC Corporation) is used.

In a case where the photosensitive resin composition includes a surfactant, a content of the surfactant is preferably 0.01% by mass to 3% by mass, more preferably 0.05% by mass to 1% by mass, and even more preferably 0.1% by mass to 0.8% by mass, with respect to the total solid content of the photosensitive resin composition.

<Polymerization Inhibitor>

The photosensitive resin composition according to the disclosure may include at least one kind of a polymerization inhibitor.

As the polymerization inhibitor, for example, a thermal polymerization inhibitor (also referred to as a polymerization inhibitor) disclosed in paragraph 0018 of JP4502784B can be used.

Among them, phenothiazine, phenoxazine, or 4-methoxyphenol can be preferably used.

In a case where the photosensitive resin composition includes a polymerization inhibitor, a content of the polymerization inhibitor is preferably 0.01% by mass to 3% by mass, more preferably 0.01% by mass to 1% by mass, and even more preferably 0.01% by mass to 0.8% by mass, with respect to the total solid content of the photosensitive resin composition.

<Hydrogen Donating Compound>

The photosensitive resin composition according to the disclosure preferably further includes a hydrogen donating compound.

In the disclosure, the hydrogen donating compound has a function of further improving sensitivity of the photopolymerization initiator to active light, or suppressing inhibition of polymerization of the polymerizable compound by oxygen.

Examples of such a hydrogen donating compound include amines, for example, M. R. Sander et al., “Journal of Polymer Society,” Vol. 10, page 3173 (1972), JP1969-020189B (JP-S-44-020189B), JP1976-082102A (JP-S-51-082102A), JP1977-134692A (JP-S-52-134692A), JP1984-138205A (JP-S-59-138205A), JP1985-084305A (JP-S-60-084305A), JP1987-018537A (JP-S-62-018537), JP1989-033104A (JP-S-64-033104A), and Research Disclosure 33825, and specific examples thereof include triethanolamine, p-dimethylaminobenzoic acid ethyl ester, p-formyldimethylaniline, and p-methylthiodimethylaniline.

In addition, other examples of the hydrogen donating compound further include an amino acid compound (for example, N-phenylglycine or the like), an organic metal compound disclosed in JP1973-042965B (JP-S-48-042965B) (for example, tributyltin acetate, or the like), a hydrogen donor disclosed in JP1980-034414B (JP-S-55-034414B), and a sulfur compound disclosed in JP1994-308727A (JP-H-6-308727A) (for example, trithiane or the like).

A content of the hydrogen donating compounds is preferably in a range of 0.1% by mass to 30% by mass, more preferably in a range of 1% by mass to 25% by mass, and even more preferably in a range of 0.5% by mass to 20% by mass, with respect to the total solid content of the photosensitive resin composition, from a viewpoint of improving a curing speed with balance between a polymerization growth speed and chain transfer.

<Other Components>

The photosensitive resin composition according to the disclosure may include a component other than the components described above.

Examples of the other components include a thermal polymerization inhibitor disclosed in paragraph 0018 of JP4502784B, and other additives disclosed in paragraphs 0058 to 0071 of JP2000-310706A.

The photosensitive resin composition may include at least one kind of particles (for example, metal oxide particles) as the other component, in order to adjust a refractive index or light transmittance.

The metal of the metal oxide particles also includes semimetal such as B, Si, Ge, As, Sb, or Te. From a viewpoint of transparency of the cured film, an average primary particle diameter of the particles (for example, metal oxide particles) is preferably 1 to 200 nm and more preferably 3 to 80 nm. The average primary particle diameter is calculated by measuring particle diameters of 200 random particles using an electron microscope and averaging the measured result. In a case where the shape of the particle is not a spherical shape, the longest side is set as the particle diameter.

The content of the particles is preferably 0% by mass to 35% by mass, more preferably 0% by mass to 10% by mass, even more preferably 0% by mass to 5% by mass, still more preferably 0% by mass to 1% by mass, and particularly preferably 0% by mass (that is, the photosensitive resin composition includes no particles), with respect to the total solid content of the photosensitive resin composition.

In addition, the photosensitive resin composition may include a small amount of colorant (pigment, dye, and the like) as the other component, but it is preferable that a colorant is not substantially included, from a viewpoint of transparency.

Specifically, a content of the colorant in the photosensitive resin composition is preferably smaller than 1% by mass and more preferably smaller than 0.1% by mass with respect to the total solid content of the photosensitive resin composition.

<Solvent>

The photosensitive resin composition according to the disclosure preferably further includes a solvent, from a viewpoint of forming a layer by applying.

As the solvent, a solvent normally used can be used without particular limitations.

The solvent is preferably an organic solvent.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. In addition, the solvent used may include a mixed solvent which is a mixture of these compounds.

As the solvent, a mixed solvent of methyl ethyl ketone and propylene glycol monomethyl ether acetate or a mixed solvent of diethylene glycol ethyl methyl ether and propylene glycol monomethyl ether acetate is preferably used.

In a case of using the solvent, a content of solid contents of the photosensitive resin composition is preferably 5% by mass to 80% by mass, more preferably 5% by mass to 40% by mass, and particularly preferably 5% by mass to 30% by mass with respect to a total amount of the photosensitive resin composition.

In a case of using the solvent, a viscosity (25° C.) of the photosensitive resin composition is preferably 1 mPa·s to 50 mPa·s, more preferably 2 mPa·s to 40 mPa·s, and particularly preferably 3 mPa·s to 30 mPa·s, from a viewpoint of coating properties.

The viscosity is, for example, measured using VISCOMETER TV-22 (manufactured by Toki Sangyo Co. Ltd.).

In a case where the photosensitive resin composition includes the solvent, a surface tension (25° C.) of the photosensitive resin composition is preferably 5 mN/m to 100 mN/m, more preferably 10 mN/m to 80 mN/m, and particularly preferably 15 mN/m to 40 mN/m, from a viewpoint of coating properties.

The surface tension is, for example, measured using Automatic Surface Tensiometer CBVP-Z (manufactured by Kyowa Interface Science Co., Ltd.).

As the solvent, a solvent disclosed in paragraphs 0054 and 0055 of US2005/282073A can also be used, and the content of this specification is incorporated in the present specification.

In addition, as the solvent, an organic solvent (high-boiling-point solvent) having a boiling point of 180° C. to 250° C. can also be used, as necessary.

(Cured Film)

The cured film according to the disclosure is a cured film obtained by curing the solid content of the photosensitive resin composition according to the disclosure. In a case where the photosensitive resin composition according to the disclosure does not include a solvent, the cured film according to the disclosure is a cured film obtained by curing the photosensitive resin composition according to the disclosure.

In a case where the photosensitive resin composition according to the disclosure includes a solvent, the photosensitive resin composition according to the disclosure is applied to a base material in a film shape. Then, it is preferable that, after removing at least a part of the solvent, the curing is performed to form a cured film, by a well-known method such as heating drying, air drying, or drying under reduced pressure.

In addition, the cured film may have a desired pattern shape.

The cured film according to the disclosure can be suitably used as an interlayer insulating film (insulating film) or an overcoat film (protective film), and is more preferably used as a protective film for a touch panel.

The cured film obtained by curing the solid content of the photosensitive resin composition according to the disclosure has excellent film physical properties, and thus is useful for usage in an organic EL display device or a liquid crystal display device.

Among these, the cured film according to the disclosure can be suitably used as a protective film for a touch panel and can be more suitably used as a protective film for touch panel wiring.

A thickness of the cured film is not particularly limited and is preferably 1 μm to 20 μm, more preferably 2 μm to 15 μm, and particularly preferably 3 μm to 12 μm.

(Transfer Film)

The transfer film according to the disclosure comprises a temporary support, and a layer including the photosensitive resin composition according to the disclosure (hereinafter, also referred to as a “photosensitive layer”).

<Temporary Support>

The transfer film according to the disclosure includes a temporary support.

The temporary support is preferably a film and more preferably a resin film.

As the temporary support, a film which has flexibility and does not generate significant deformation, shrinkage, or stretching under pressure or under pressure and heating can be used.

Examples of such a film include a polyethylene terephthalate film, a cellulose triacetate film, a polystyrene film, a polyimide film, and a polycarbonate film.

Among these, a biaxial stretching polyethylene terephthalate film is particularly preferable.

It is preferable that the film used as the temporary support does not have deformation such as wrinkles or scratches.

A haze of the film used as the temporary support is preferably 1.0% or less, and a total number of particles having a diameter of 5 μm or more and aggregates having a diameter of 5 μm or more included in the film is preferably 5 piece/mm² or less.

In addition, on both surfaces of the temporary support that is a surface not in contact with the photosensitive layer and a surface in contact with the photosensitive layer, a density of broken bubble marks having a diameter of 40 μm to 100 μm caused by rupture of bubbles in the resin of the temporary support is preferably 5 piece/0.25 m² or less.

Examples of the biaxial stretching polyethylene terephthalate film satisfying the above include LUMIRROR 16QS62 (manufactured by Toray Industries, Inc.), LUMIRROR 16QS52 (manufactured by Toray Industries, Inc.), and LUMIRROR 16QS48 (manufactured by Toray Industries, Inc.).

A thickness of the temporary support is not particularly limited, and is, for example, preferably 5 μm to 200 and is particularly preferably 10 μm to 150 from viewpoints of ease of handling and general-purpose properties.

### <Photosensitive Layer>

The transfer film according to the disclosure comprises a layer including the photosensitive resin composition according to the disclosure (photosensitive layer).

The photosensitive layer may be a layer including the photosensitive resin composition according to the disclosure, but is preferably a layer consisting of the photosensitive resin composition according to the disclosure or a layer consisting of a solid content of the photosensitive resin composition according to the disclosure.

In a case where the photosensitive resin composition includes a solvent, it is preferable that at least a part of the solvent is removed by a well-known method to form the photosensitive layer. The solvent does not have to be completely removed, but the content of the solvent in the photosensitive layer is preferably 1% by mass or less and more preferably 0.5% by mass or less, with respect to a total mass of the photosensitive layer.

A thickness of the photosensitive layer is preferably 20 μm or less, more preferably 15 μm or less, and particularly preferably 12 μm or less.

It is advantageous in a case where the thickness of the photosensitive layer is 20 μm or less, from viewpoints of reducing a thickness of the entire transfer film, improving transmittance of the photosensitive layer or the cured film to be obtained, and preventing yellowing of the photosensitive layer or the cured film to be obtained.

From a viewpoint of manufacturing suitability, the thickness of the photosensitive layer is preferably 0.5 μm or more, more preferably 1 μm or more, and particularly preferably 2 μm or more.

A refractive index of the photosensitive layer is preferably 1.47 to 1.56, more preferably 1.48 to 1.55, even more preferably 1.49 to 1.54, and particularly preferably 1.50 to 1.53.

In the disclosure, the “refractive index” indicates a refractive index at a wavelength of 550 nm.

The “refractive index” in the disclosure means a value measured with visible light at a wavelength of 550 nm at a temperature of 23° C. by ellipsometry, unless otherwise noted.

A method for forming the photosensitive layer is not particularly limited, and a well-known method can be used.

As an example of the method for forming the photosensitive layer, a method forming the photosensitive layer by applying a photosensitive resin composition containing a solvent onto a temporary support and then drying, as necessary is used.

As the coating method, a well-known method can be used, and examples thereof include a printing method, a spray coating method, a roll coating method, a bar coating method, a curtain coating method, a spin coating method, and a die coating method (that is, slit coating method), and a die coating method is preferable.

As the drying method, a well-known method such as natural drying, heating drying, and drying under reduced pressure can be applied alone or in combination of plural thereof.

<Second Resin Layer>

The transfer film according to the disclosure may further comprise a second resin layer on a side opposite to a side where the temporary support is present, when seen from the photosensitive layer (for example, see specific example of the transfer film which will be described later).

As the second resin layer, a refractive index adjusting layer is preferably used.

According to the transfer film of the embodiment comprising the refractive index adjusting layer, in a case of forming a protective layer for a touch panel by transferring the refractive index adjusting layer and the photosensitive layer of the transfer film to a substrate for a touch panel comprising a transparent electrode pattern, the transparent electrode pattern is more hardly recognized (that is, concealing properties of the transparent electrode pattern are further improved). A phenomenon that the transparent electrode pattern is recognized, is generally referred to as “see-through”.

Regarding the phenomenon that the transparent electrode pattern is recognized, and the concealing properties of the transparent electrode pattern, JP2014-010814A and JP2014-108541A can be suitably referred to.

The second resin layer is preferably disposed to be adjacent to the photosensitive layer.

The refractive index of the second resin layer is preferably higher than the refractive index of the photosensitive layer, from a viewpoint of preventing the see-through.

The refractive index of the second resin layer is preferably equal to or greater than 1.50, more preferably equal to or greater than 1.55, and particularly preferably equal to or greater than 1.60.

An upper limit of the refractive index of the second resin layer is not particularly limited, and is preferably equal to or smaller than 2.10, more preferably equal to or smaller than 1.85, even more preferably equal to or smaller than 1.78, and particularly preferably equal to or smaller than 1.74.

The second resin layer may have photocuring properties (that is, photosensitivity), may have thermosetting properties, or may have both photocuring properties and thermosetting properties.

From a viewpoint of forming the cured film having excellent hardness by the photocuring after the transfer, the second resin layer preferably has photocuring properties.

From viewpoints of further improving hardness of the cured film by the heat curing, the second resin layer preferably has thermosetting properties.

The second resin layer preferably has thermosetting properties and photocuring properties.

The second resin layer preferably has alkali solubility (for example, solubility with respect to weak alkali aqueous solution).

The embodiment in which the second resin layer has photosensitivity, has an advantage, from a viewpoint of collectively patterning the photosensitive layer and the second resin layer transferred onto the substrate by photolithography at one time, after the transferring.

A film thickness of the second resin layer is preferably equal to or smaller than 500 nm, more preferably equal to or smaller than 110 nm, and particularly preferably equal to or smaller than 100 nm.

In addition, the film thickness of the second resin layer is preferably equal to or greater than 20 nm, more preferably equal to or greater than 50 nm, even more preferably equal to or greater than 55 nm, and particularly preferably equal to or greater than 60 nm.

The refractive index of the second resin layer is preferably adjusted in accordance with the refractive index of the transparent electrode pattern.

For example, in a case where the refractive index of the transparent electrode pattern is 1.8 to 2.0, as in a case of the transparent electrode pattern consisting of indium tin oxide (ITO), the refractive index of the second resin layer is preferably equal to or greater than 1.60. An upper limit of the refractive index of the second resin layer in this case is not particularly limited, and is preferably equal to or smaller than 2.1, more preferably equal to or smaller than 1.85, even more preferably equal to or smaller than 1.78, and particularly preferably equal to or smaller than 1.74.

In addition, in a case where the refractive index of the transparent electrode pattern is greater than 2.0, as in a case of the transparent electrode pattern consisting of indium zinc oxide (IZO), for example, the refractive index of the second resin layer is preferably 1.70 to 1.85.

A method for controlling the refractive index of the second resin layer is not particularly limited, and examples thereof include a method using a resin having a predetermined refractive index alone, a method using a resin and metal oxide particles and metal particles, and a method using a composite of metal salt and a resin.

The second resin layer preferably includes at least one kind selected from the group consisting of inorganic particles having a refractive index equal to or greater than 1.50 (more preferably equal to or greater than 1.55, and particularly preferably equal to or greater than 1.60), a resin having a refractive index equal to or greater than 1.50 (more preferably equal to or greater than 1.55, and particularly preferably equal to or greater than 1.60), and a polymerizable monomer having a refractive index equal to or greater than 1.50 (more preferably equal to or greater than 1.55, and particularly preferably equal to or greater than 1.60).

According to this embodiment, the refractive index of the second resin layer is easily adjusted to be equal to or greater than 1.50 (more preferably equal to or greater than 1.55, and particularly preferably equal to or greater than 1.60).

In addition, the second resin layer preferably includes a binder polymer, an ethylenically unsaturated compound, and particles.

Regarding the components of the second resin layer, components of a curable second resin layer disclosed in paragraphs 0019 to 0040 and 0144 to 0150 of JP2014-108541A, and components of a transparent layer disclosed in paragraphs 0024 to 0035 and 0110 to 0112 of JP2014-010814A, and components of a composition including ammonium salt disclosed in paragraphs 0034 to 0056 of WO2016/009980A can be referred to.

In addition, the second resin layer preferably includes at least one kind of a metal oxidation inhibitor.

In a case where the second resin layer includes the metal oxidation inhibitor, surface treatment can be performed with respect to a member (for example, conductive member formed on a substrate) in a direct contact with the second resin layer, in a case of transferring the second resin layer onto the substrate (that is, a target to be transferred). This surface treatment applies a metal oxide inhibiting function (protection properties) with respect to the member in a direct contact with the second resin layer.

Examples of the metal oxidation inhibitor include those mentioned above.

The second resin layer of the disclosure may include a component other than the components described above.

The other component which can be included in the second resin layer is the same as the other component which can be included in the photosensitive layer described above.

The second resin layer preferably includes a surfactant as the other component.

A forming method of the second resin layer is not particularly limited.

As an example of the forming method of the second resin layer, a method of forming the layer by applying and, as necessary, drying a composition for forming a second resin layer of the embodiment including an aqueous solvent, on the photosensitive layer formed on the temporary support is used.

Specific examples of the coating and drying method are respectively the same as the specific examples of the coating and drying in a case of forming the photosensitive layer.

The composition for forming the second resin layer can include each component of the second resin layer described above.

The composition for forming the second resin layer, for example, includes a binder polymer, an ethylenically unsaturated compound, particles, and an aqueous solvent.

In addition, as the composition for forming the second resin layer, a composition including ammonium salt disclosed in paragraphs 0034 to 0056 of WO2016/009980A is also preferable.

<Protective Film>

The transfer film according to the disclosure may further comprise a protective film on a side of the photosensitive layer opposite to the temporary support.

In a case where the transfer film according to the disclosure comprises the second resin layer on a side of the photosensitive layer opposite to the temporary support, the protective film is preferably disposed on a side opposite to the temporary support from the view of the second resin layer.

Examples of the protective film include a polyethylene terephthalate film, a polypropylene film, a polystyrene film, and a polycarbonate film.

It is preferable that the film used as the protective film does not have deformation such as wrinkles or scratches.

A haze of the film used as the protective film is preferably 1.0% or less, and a total number of particles having a diameter of 5 μm or more and aggregates having a diameter of 5 μm or more included in the film is preferably 5 piece/mm² or less.

In addition, on both surfaces of the protective film that is a surface not in contact with the photosensitive resin layer and a surface in contact with the photosensitive resin layer, a density of broken bubble marks having a diameter of 40 μm to 100 μm caused by rupture of bubbles in the resin of the protective film is preferably 5 piece/0.25 m² or less.

Examples of the protective film satisfying the above include LUMIRROR 16QS62 (manufactured by Toray Industries, Inc.), LUMIRROR 16QS52 (manufactured by Toray Industries, Inc.), LUMIRROR 16QS48 (manufactured by Toray Industries, Inc.), TORAYFAN 12KW37 (manufactured by Toray Industries, Inc.), TORAYFAN 25KW37 (manufactured by Toray Industries, Inc.), ALPHAN E-501L (Oji F-Tex Co., Ltd.), and ALPHAN HS-501 (Oji F-tex Co., Ltd.).

A thickness of the protective film is not particularly limited, and is, for example, preferably 5 μm to 200 μm, and is particularly preferably 10 μm to 150 μm, from viewpoints of ease of handling and general-purpose properties.

<Thermoplastic Resin Layer>

The transfer film according to the disclosure may further comprise a thermoplastic resin layer between a temporary support and a photosensitive layer.

In a case where the transfer film comprises the thermoplastic resin layer and the transfer film is transferred to a substrate to form a laminate, air bubbles are hardly generated on each element of the laminate. In a case where this laminate is used in an image display device, image unevenness is hardly generated and excellent display properties are obtained.

The thermoplastic resin layer preferably has alkali solubility.

The thermoplastic resin layer functions as a cushion material which absorbs ruggedness of the surface of the substrate at the time of transfer.

The ruggedness of the surface of the substrate includes an image, an electrode, a wiring, and the like which are formed in advance. The thermoplastic resin layer preferably has properties capable of being deformed in accordance with ruggedness.

The thermoplastic resin layer preferably includes an organic polymer substance disclosed in JP1993-072724A (JP-H5-072724A), and more preferably includes an organic polymer substance having a softening point approximately equal to or lower than 80° C. by a Vicat method (specifically, polymer softening point measurement method using an American Society for Testing and Materials ASTM D1235).

A thickness of the thermoplastic resin layer is preferably 3 μm to 30 v, more preferably 4 μm to 25 μm, and even more preferably 5 μm to 20 μm.

In a case where the thickness of the thermoplastic resin layer is equal to or greater than 3 μm, followability with respect to the ruggedness of the surface of the substrate is improved, and accordingly, the ruggedness of the surface of the substrate can be effectively absorbed.

In a case where the thickness of the thermoplastic resin layer is equal to or smaller than 30 μm, process suitability is further improved. For example, burden of the drying (solvent removal) in a case of applying and forming the thermoplastic resin layer on the temporary support is further reduced, and the development time of the thermoplastic resin layer after the transfer is shortened.

The thermoplastic resin layer can be formed by applying and, as necessary, drying a composition for forming a thermoplastic resin layer including a solvent and a thermoplastic organic polymer on the temporary support.

Specific examples of the coating and drying method are respectively the same as the specific examples of the coating and drying in a case of forming the photosensitive layer.

The solvent is not particularly limited, as long as a polymer component forming the thermoplastic resin layer is dissolved, and examples thereof include organic solvents (for example, methyl ethyl ketone, cyclohexanone, propylene glycol monomethyl ether acetate, n-propanol, and 2-propanol).

A viscosity of the thermoplastic resin layer measured at 100° C. is preferably 1,000 to 10,000 Pa·s. In addition, the viscosity of the thermoplastic resin layer measured at 100° C. is preferably lower than the viscosity of the photosensitive layer measured at 100° C.

<Interlayer>

The transfer film according to the disclosure may further comprise a photosensitive resin layer between a temporary support and an interlayer.

In a case where the transfer film according to the disclosure comprises the thermoplastic resin layer, the interlayer is preferably disposed between the thermoplastic resin layer and the photosensitive layer.

As the component of the interlayer, a resin which is a mixture including polyvinyl alcohol, polyvinyl pyrrolidone, cellulose, or at least two kinds thereof.

In addition, as the interlayer, a component disclosed in JP1993-072724A (JP-H5-072724A) as a “separation layer” can also be used.

In a case of producing the transfer film of the embodiment comprising the thermoplastic resin layer, the interlayer, and the photosensitive layer on the temporary support in this order, the interlayer can be, for example, formed by applying and, as necessary, drying a composition for forming an interlayer including a solvent which does not dissolve the thermoplastic resin layer, and the resin as the component of the interlayer. Specific examples of the coating and drying method are respectively the same as the specific examples of the coating and drying in a case of forming the photosensitive layer.

In this case, for example, first, the composition for forming a thermoplastic resin layer is applied and dried on the temporary support to form the thermoplastic resin layer. Next, the composition for forming an interlayer is applied and dried on this thermoplastic resin layer to form the interlayer. After that, the photosensitive resin composition of the embodiment including the organic solvent is applied and dried on the interlayer to form the photosensitive layer. The organic solvent in this case is preferably an organic solvent which does not dissolve the interlayer.

<Specific Examples of Transfer Film>

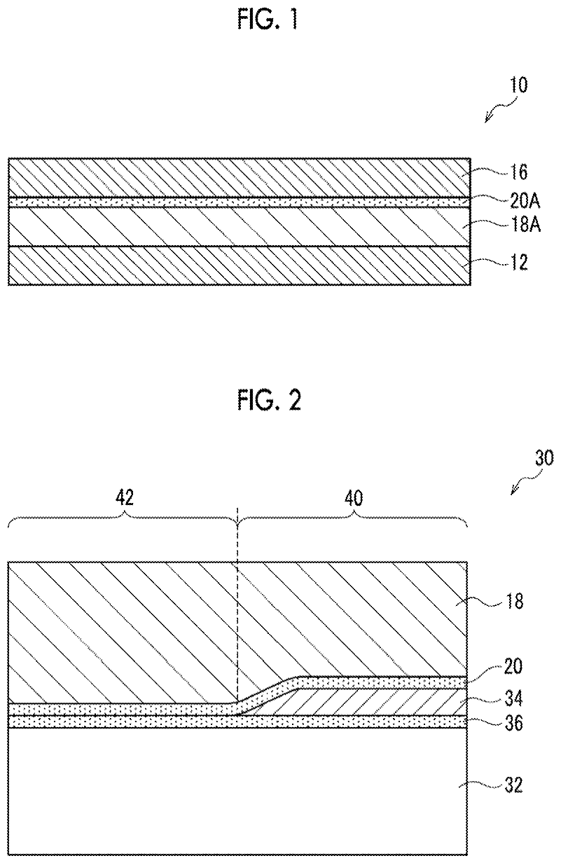

FIG. 1 is a schematic cross sectional view of a transfer film 10 which is a specific example of the transfer film according to the disclosure.

As shown in FIG. 1, the transfer film 10 has a laminated structure of “protective film 16/second resin layer 20A/photosensitive layer 18A/temporary support 12” (that is, laminated structure in which a temporary support 12, a photosensitive layer 18A, a second resin layer 20A, and a protective film 16 are arranged in this order).

However, the transfer film according to the disclosure is not limited to the transfer film 10, and the second resin layer 20A and the protective film 16 may be omitted, for example. In addition, at least one of the thermoplastic resin layer or the interlayer described above may be comprised between the temporary support 12 and the photosensitive layer 18A.

The second resin layer 20A is a layer disposed on a side of the photosensitive layer 18A opposite to the side where the temporary support 12 is present, and a layer having a refractive index at a wavelength of 550 nm equal to or greater than 1.50.

The transfer film 10 is a negative type material (negative type film).

A manufacturing method of the transfer film 10 is not particularly limited.

The manufacturing method of the transfer film 10, for example, includes a step of forming the photosensitive layer 18A on the temporary support 12, a step of forming the second resin layer 20A on the photosensitive layer 18A, and a step of forming the protective film 16 on the second resin layer 20A in this order.

The manufacturing method of the transfer film 10 may include a step of volatilizing ammonia disclosed in a paragraph 0056 of WO2016/009980A, between the step of forming the second resin layer 20A and the step of forming the protective film 16.

(Laminate and Capacitive Input Device)

The laminate according to the disclosure described below may include the cured film according to the disclosure, but is preferably a laminate obtained by laminating a substrate, an electrode, and the cured film according to the disclosure in this order.

In addition, the photosensitive layer may have a desired pattern shape.

Further, the laminate according to the disclosure preferably includes the photosensitive layer after removing the temporary support from the transfer film according to the disclosure on the substrate.

The capacitive input device according to the disclosure includes the cured film according to the disclosure or the laminate according to the disclosure.

The substrate is preferably a substrate including an electrode of the capacitive input device.

In addition, the electrode is preferably an electrode of an electrode of the capacitive input device.

The electrode of the capacitive input device may be a transparent electrode pattern or a leading wiring. In the laminate, the electrode of the capacitive input device is preferably an electrode pattern and more preferably a transparent electrode pattern.

It is preferable that the laminate according to the disclosure includes a substrate, a transparent electrode pattern, a second resin layer disposed to be adjacent to the transparent electrode pattern, and a photosensitive layer disposed to be adjacent to the second resin layer, and a refractive index of the second resin layer is higher than a refractive index of the photosensitive layer. The refractive index of the second resin layer is preferably equal to or greater than 1.6.

With the configuration of the laminated described above, the concealing properties of the transparent electrode pattern is improved.

As the substrate, a glass substrate or a resin substrate is preferable.

In addition, the substrate is preferably a transparent substrate and more preferably a transparent resin substrate. The transparency in the disclosure means that the transmittance of all visible light is 85% or more, preferably 90% or more, and more preferably 95% or more.

A refractive index of the substrate is preferably 1.50 to 1.52.

As the glass substrate, tempered glass such as GORILLA GLASS (registered trademark) manufactured by Corning Incorporated can be used.

As the resin substrate, at least one of a component with no optical strains or a component having high transparency is preferably used, and a substrate formed of a resin such as polyethylene terephthalate (PET), polyethylene naphthalate (PEN), polycarbonate (PC), triacetyl cellulose (TAC), polyimide (PI), polybenzoxazole (PBO), or cycloolefin polymer (COP) is used, for example.

As a material of the transparent substrate, a material disclosed in JP2010-086684A, JP2010-152809A, and JP2010-257492A is preferably used.

As the capacitive input device, a touch panel is suitably used.

As the electrode for a touch panel, a transparent electrode pattern disposed at least in an image display region of the touch panel is used. The electrode for a touch panel may extend from the image display region to a frame portion of the touch panel.

As the wiring for a touch panel, the leading wiring (lead-out wiring) disposed on the frame portion of the touch panel is used, for example.

As a preferred embodiment of the substrate for a touch panel and the touch panel, an embodiment in which the transparent electrode pattern and the leading wiring are electrically connected to each other by laminating a part of the leading wiring on a portion of the transparent electrode pattern extending to the frame portion of the touch panel, is suitable.

As a material of the transparent electrode pattern, a metal oxide film of indium tin oxide (ITO) and indium zinc oxide (IZO) is preferable.

As a material of the leading wiring, metal is preferable. Examples of the metal which is the material of the leading wiring include gold, silver, copper, molybdenum, aluminum, titanium, chromium, zinc, and manganese, and alloy formed of two or more kinds of these metal elements. As the material of the leading wiring, copper, molybdenum, aluminum, or titanium is preferable, copper is particularly preferable.

The electrode protective layer for a touch panel according to the disclosure is provided so as to cover the electrode and the like directly or through other layers, in order to protect the electrode and the like (that is, at least one of the electrode for a touch panel or the wiring for a touch panel).

The preferred range of a thickness of the electrode protective film for a touch panel is the same as the preferred range of a thickness of the photosensitive layer described above.

The electrode protective film according to the disclosure, preferably the electrode protective film for a touch panel may include an opening.

The opening can be formed by dissolving an unexposed portion of the photosensitive layer with a developer.

In this case, in a case where the electrode protective film for a touch panel is formed under the laminating condition at a high temperature using the transfer film, the development residue of the opening of the electrode protective film for a touch panel is prevented.

The touch panel may further comprise a first refractive index adjusting layer between the electrode and the like and the electrode protective layer for a touch panel (for example, see first specific example of the touch panel which will be described later).

The preferred embodiment of the first refractive index adjusting layer is the same as the preferred embodiment of the second resin layer comprised in the transfer film. The first refractive index adjusting layer may be formed by applying and drying a composition for forming the first refractive index adjusting layer, or may be formed by transferring the refractive index adjusting layer of the transfer film comprising the refractive index adjusting layer.

The touch panel of the embodiment comprising the first refractive index adjusting layer is preferably formed by transferring the photosensitive layer and the second resin layer of the transfer film by using the transfer film according to the disclosure of the embodiment comprising the second resin layer. In this case, the electrode protective film for a touch panel is formed of the photosensitive layer of the transfer film, and the first refractive index adjusting layer is formed of the second resin layer of the transfer film.

In addition, the touch panel or the substrate for a touch panel may comprise a second refractive index adjusting layer between the substrate and the electrode and the like (for example, see, first specific example of the touch panel which will be described later).

The preferred embodiment of the second refractive index adjusting layer is the same as the preferred embodiment of the second resin layer comprised in the transfer film.

The embodiment in which the touch panel of the disclosure comprises the first refractive index adjusting layer (more preferably, embodiment of comprising the first refractive index adjusting layer and the second refractive index adjusting layer) has an advantage in which the electrode and the like are hardly recognized (that is, so-called see-through is prevented).

Regarding the structure of the touch panel, a structure of a capacitive input device disclosed in JP2014-010814A or JP2014-108541A may be referred to.

<First Specific Example of Touch Panel>

FIG. 2 is a schematic cross sectional view of a touch panel 30 which is the first specific example of the touch panel according to the disclosure. More specifically, FIG. 2 is a schematic cross sectional view of an image display region of the touch panel 30.

As shown in FIG. 2, the touch panel 30 has a structure in which a substrate 32, a second refractive index adjusting layer 36, a transparent electrode pattern 34 as the electrode for a touch panel, a first refractive index adjusting layer 20, and an electrode protective film 18 for a touch panel are disposed in this order.

In the touch panel 30, the electrode protective film 18 for a touch panel and the first refractive index adjusting layer 20 cover the entire transparent electrode pattern 34. However, the touch panel according to the disclosure is not limited to this embodiment. The electrode protective film 18 for a touch panel and the first refractive index adjusting layer 20 may cover at least a portion of the transparent electrode pattern 34.

In addition, the second refractive index adjusting layer 36 and the first refractive index adjusting layer 20 are preferably respectively continuously coated over a first region 40 in which the transparent electrode pattern 34 is present and a second region 42 in which the transparent electrode pattern 34 is not present directly or through another layer. Accordingly, the transparent electrode pattern 34 is more hardly recognized.

The second refractive index adjusting layer 36 and the first refractive index adjusting layer 20 are preferably coated directly over both of the first region 40 and the second region 42, rather than the coating through the other layer. Examples of the “other layer” include an insulating layer and an electrode pattern other than the transparent electrode pattern 34.

The first refractive index adjusting layer 20 is laminated over both of the first region 40 and the second region 42. The first refractive index adjusting layer 20 is adjacent to the second refractive index adjusting layer 36 and is also adjacent to the transparent electrode pattern 34.

In a case where the shape of the end portion of the transparent electrode pattern 34 at a portion in contact with the second refractive index adjusting layer 36 is a tapered shape as shown in FIG. 2, the first refractive index adjusting layer 20 is preferably laminated along the tapered shape (that is, at the same tilt as the taper angle).

As the transparent electrode pattern 34, the ITO transparent electrode pattern is suitable.

The transparent electrode pattern 34 can be, for example, formed by the following method.

A thin film for an electrode (for example, ITO film) is formed on the substrate 32 on which the second refractive index adjusting layer 36 is formed by sputtering. By applying a photosensitive resist for etching or transferring a photosensitive film for etching onto the thin film for an electrode, an etching protective layer is formed. Then, this etching protective layer is patterned in a desired pattern shape by exposure and development. Next, a portion of the thin film for an electrode which is not covered with the patterned etching protective layer is removed by etching. Accordingly, the thin film for an electrode is set to have a pattern having a desired shape (that is, transparent electrode pattern 34). Then, the patterned etching protective layer is removed by a peeling solution.

The first refractive index adjusting layer 20 and the electrode protective film 18 for a touch panel are, for example, formed on the substrate 32 (that is, substrate for a touch panel) on which the second refractive index adjusting layer 36 and the transparent electrode pattern 34 are provided in order, as described below.

First, the transfer film 10 (that is, transfer film 10 having a laminated structure of “protective film 16/second resin layer 20A/photosensitive layer 18A/temporary support 12”) shown in FIG. 1 is prepared.

Next, the protective film 16 is removed from the transfer film 10.

Then, the transfer film 10, from which the protective film 16 is removed, is laminated on the substrate 32 (that is, substrate for a touch panel) on which the second refractive index adjusting layer 36 and the transparent electrode pattern 34 are provided in order. The laminating is performed in a direction in which the second resin layer 20A of the transfer film 10, from which the protective film 16 is removed, and the transparent electrode pattern 34 are in contact with each other. By this laminating, a laminate having a laminated structure of “temporary support 12/photosensitive layer 18A/second resin layer 20A/transparent electrode pattern 34/second refractive index adjusting layer 36/substrate 32” is obtained.

Next, the temporary support 12 is removed from the laminate.

Then, by performing the pattern exposure with respect to the laminate, from which the temporary support 12 is removed, the photosensitive layer 18A and the second resin layer 20A are cured in a pattern shape. The curing of the photosensitive layer 18A and the second resin layer 20A in a pattern shape may be respectively individually performed by individual pattern exposure, but the curing is preferably performed at the same time by the pattern exposure at one time.

Next, by removing the unexposed portion (that is, uncured portion) of the photosensitive layer 18A and the second resin layer 20A by the development, the electrode protective film 18 for a touch panel which is a patterned cured product of the photosensitive layer 18A (not shown regarding the pattern shape), and the first refractive index adjusting layer 20 which is a patterned cured product of the second resin layer 20A (not shown regarding the pattern shape) are respectively obtained. The development of the photosensitive layer 18A and the second resin layer 20A after the pattern exposure may be respectively individually performed by individual development, but the development is preferably performed at the same time by the development at one time.

The preferred embodiments of the laminating, the pattern exposure, and the development will be described later.

Regarding the structure of the touch panel, a structure of a capacitive input device disclosed in JP2014-010814A or JP2014-108541A may be referred to.

<Second Specific Example of Touch Panel>

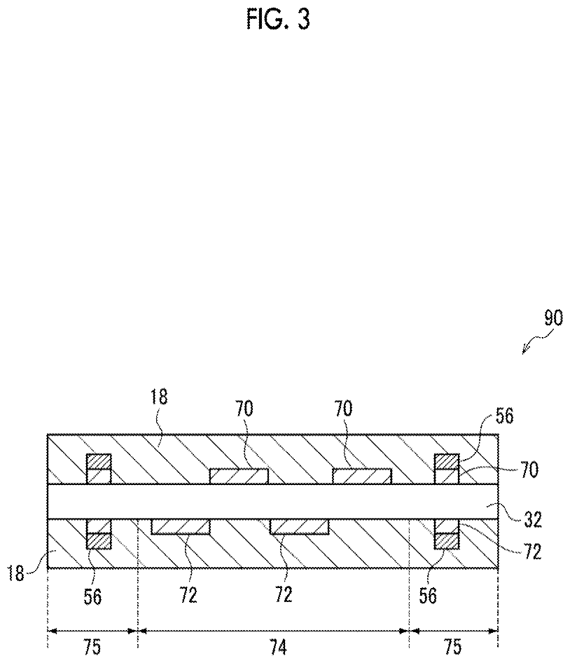

FIG. 3 is a schematic cross sectional view of a touch panel 90 which is a second specific example of the touch panel according to the disclosure.

As shown in FIG. 3, the touch panel 90 includes an image display region 74 and an image non-display region 75 (that is, frame portion).

As shown in FIG. 3, the touch panel 90 comprises the electrode for a touch panel on both surfaces of the substrate 32. Specifically, the touch panel 90 comprises a first transparent electrode pattern 70 on one surface of the substrate 32 and comprises a second transparent electrode pattern 72 on the other surface thereof.

In the touch panel 90, a leading wiring 56 is connected to the first transparent electrode pattern 70 and the second transparent electrode pattern 72, respectively. The leading wiring 56 is, for example, a copper wiring.

In the touch panel 90, the electrode protective film 18 for a touch panel is formed on one surface of the substrate 32 so as to cover the first transparent electrode pattern 70 and the leading wiring 56, and the electrode protective film 18 for a touch panel is formed on the other surface of the substrate 32 so as to cover the second transparent electrode pattern 72 and the leading wiring 56.

The first refractive index adjusting layer and the second refractive index adjusting layer of the first specific example may be provided on the one surface and the other surface of the substrate 32, respectively.

<Manufacturing Method of Touch Panel>

The method of manufacturing the touch panel according to the disclosure is not particularly limited, and the following manufacturing method is preferable.

The preferred manufacturing method of the touch panel according to the disclosure includes

a step of preparing a substrate for a touch panel having a structure in which the electrode and the like (that is, at least one of the electrode for a touch panel or the wiring for a touch panel) are disposed on a substrate (hereinafter, also referred to as a “preparation step”),

a step of forming a photosensitive layer on a surface of the substrate for a touch panel, on a side where the electrode and the like are disposed, using the transfer film according to the disclosure (hereinafter, also referred to as a “photosensitive layer forming step”),

a step of performing the pattern exposure with respect to the photosensitive layer formed on the surface of the substrate for a touch panel (hereinafter, also referred to as a “pattern exposure step”), and

a step of developing the patternwise exposed photosensitive layer to obtain an electrode protective film for a touch panel which protects at least a part of the electrode or the like (hereinafter, also referred to as a “development step”).

According to the preferred manufacturing method, a touch panel comprising the electrode protective film for a touch panel having excellent bending resistance can be manufactured.

In addition, in the preferred manufacturing method, even in a case where the photosensitive layer is formed under the laminating condition at a high temperature using the transfer film according to the disclosure, the occurrence of the development residue is prevented in the unexposed portion of the photosensitive layer after the development.

Hereinafter, each step of the preferred manufacturing method will be described.

<Preparation Step>

The preparation step is a step for convenience, and is a step of preparing a substrate for a touch panel having a structure in which the electrode and the like (that is, at least one of the electrode for a touch panel or the wiring for a touch panel) are disposed on the substrate.

The preparation step may be a step of only simply preparing the substrate for a touch panel manufactured in advance, or may be a step of manufacturing the substrate for a touch panel.

The preferred embodiment of the substrate for a touch panel is as described above.

<Photosensitive Layer Forming Step>

The photosensitive layer forming step is a step of forming a photosensitive layer on a surface of the substrate for a touch panel, on a side where the electrode and the like are disposed, using the transfer film according to the disclosure.

Hereinafter, in the photosensitive layer forming step, the embodiment using the transfer film according to the disclosure will be described.

In this embodiment, the photosensitive layer is formed on the surface by laminating the transfer film according to the disclosure on the surface of the substrate for a touch panel on a side on which the electrode and the like are disposed, and transferring the photosensitive layer of the transfer film according to the disclosure on the surface.

The laminating (transfer of the photosensitive layer) can be performed using a well-known laminator such as a vacuum laminator or an auto-cut laminator.

As the laminating condition, a general condition can be applied.

The laminating temperature is preferably 80° C. to 150° C., more preferably 90° C. to 150° C., and particularly preferably 100° C. to 150° C.

As described above, in the embodiment using the transfer film according to the disclosure, even in a case where the laminating temperature is a high temperature (for example, 120° C. to 150° C.), the occurrence of the development residue due to thermal fogging is prevented.

In a case of using a laminator comprising a rubber roller, the laminating temperature indicates a temperature of the rubber roller.

A temperature of the substrate in a case of laminating is not particularly limited. The temperature of the substrate at the time of laminating is 10° C. to 150° C., preferably 20° C. to 150° C., and more preferably 30° C. to 150° C. In a case of using a resin substrate as the substrate, the temperature of the substrate at the time of laminating is preferably 10° C. to 80° C., more preferably 20° C. to 60° C., and particularly preferably 30° C. to 50° C.

In addition, linear pressure at the time of laminating is preferably 0.5 N/cm to 20 N/cm, more preferably 1 N/cm to 10 N/cm, and particularly preferably 1 N/cm to 5 N/cm.

In addition, a transportation speed (laminating speed) at the time of laminating is preferably 0.5 m/min to 5 m/min and more preferably 1.5 m/min to 3 m/min.

In a case of using the transfer film having a laminated structure of “the protective film/photosensitive layer/interlayer/thermoplastic resin layer/temporary support”, first, the protective film is peeled off from the transfer film to expose the photosensitive layer, the transfer film and the substrate for a touch panel are bonded to each other so that the exposed photosensitive layer and the surface of the substrate for a touch panel on a side on which the electrode and the like are disposed are in contact with each other, and heating and pressurizing are performed. Accordingly, the photosensitive layer of the transfer film is transferred onto the surface of the substrate for a touch panel on a side on which the electrode and the like are disposed, and a laminate having a laminated structure of “temporary support/thermoplastic resin layer/interlayer/photosensitive layer/electrode and the like/substrate” is formed. In this laminated structure, the portion of “electrode and the like/substrate” is the substrate for a touch panel.

After that, the temporary support is peeled off from the laminate, as necessary. However, the pattern exposure which will be described later can be also performed, by leaving the temporary support.

As an example of the method of transferring the photosensitive layer of the transfer film on the substrate for a touch panel and performing pattern exposure and development, a description disclosed in paragraphs 0035 to 0051 of JP2006-023696A can also be referred to.

<Pattern Exposure Step>

The pattern exposure step is a step of performing the pattern exposure with respect to the photosensitive layer formed on the substrate for a touch panel.

Here, the pattern exposure indicates exposure of the embodiment of performing the exposure in a pattern shape, that is, the embodiment in which an exposed portion and an unexposed portion are present.

The exposed portion of the photosensitive layer on the substrate for a touch panel in the pattern exposure is cured and finally becomes the cured film.

Meanwhile, the unexposed portion of the photosensitive layer on the substrate for a touch panel in the pattern exposure is not cured, and is removed (dissolved) with a developer in the subsequent development step. With the unexposed portion, the opening of the cured film can be formed after the development step.

The pattern exposure may be exposed through a mask or may be digital exposure using a laser or the like.

As a light source of the pattern exposure, a light source can be suitably selected, as long as it can emit light at a wavelength region (for example, 365 nm or 405 nm) at which the photosensitive layer can be cured. Examples of the light source include various lasers, a light emitting diode (LED), an ultra-high pressure mercury lamp, a high pressure mercury lamp, and a metal halide lamp. An exposure intensity is preferably 5 mJ/cm² to 200 mJ/cm², and more preferably 10 mJ/cm² to 200 mJ/cm².

In a case where the photosensitive layer is formed on the substrate using the transfer film, the pattern exposure may be performed after peeling the temporary support, or the temporary support may be peeled off after performing the exposure before peeling off the temporary support.

In addition, in the exposure step, the heat treatment (so-called post exposure bake (PEB)) may be performed with respect to the photosensitive layer after the pattern exposure and before the development.

<Development Step>

The development step is a step of obtaining the electrode protective film for a touch panel which protects at least a portion of the electrode and the like, by developing the patternwise exposed photosensitive layer (that is, by dissolving the unexposed portion of the pattern exposure with a developer).

A developer used in the development is not particularly limited, and a well-known developer such as a developer disclosed in JP1993-072724A (JP-H5-072724A) can be used.

As the developer, an alkali aqueous solution is preferably used.

Examples of the alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkali aqueous solution at 25° C. is preferably 8 to 13, more preferably 9 to 12, and particularly preferably 10 to 12.

A content of the alkali compound in the alkali aqueous solution is preferably 0.1% by mass to 5% by mass and more preferably 0.1% by mass to 3% by mass with respect to a total amount of the alkali aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

A concentration of the organic solvent is preferably 0.1% by mass to 30% by mass.

The developer may include a well-known surfactant. A concentration of the surfactant is preferably 0.01% by mass to 10% by mass.

A liquid temperature of the developer is preferably 20° C. to 40° C.

Examples of the development method include methods such as puddle development, shower development, shower and spin development, and dip development.

In a case of the shower development, the unexposed portion of the photosensitive layer is removed by spraying the developer to the photosensitive layer after the pattern exposure as a shower. In a case of using the transfer film comprising at least one of the photosensitive layer, the thermoplastic resin layer, or the interlayer, after the transfer of these layers onto the substrate and before the development of the photosensitive layer, an alkali solution having a low solubility of the photosensitive layer may be sprayed as a shower, and at least one of the thermoplastic resin layer or the interlayer (both layers, in a case where both layers are present) may be removed in advance.

In addition, after the development, the development residue is preferably removed by spraying a cleaning agent with a shower and rubbing with a brush or the like.

A liquid temperature of the developer is preferably 20° C. to 40° C.

The development step may include a stage of performing the development, and a stage of performing the heat treatment (hereinafter, also referred to as “post baking”) with respect to the cured film obtained by the development.

In a case where the substrate is a resin substrate, a temperature of the post baking is preferably 100° C. to 160° C. and more preferably 130° C. to 160° C.

A resistance value of the transparent electrode pattern can also be adjusted by this post baking.

In addition, in a case where the photosensitive layer includes a carboxy group-containing (meth)acrylic resin, at least a part of the carboxy group-containing (meth)acrylic resin can be changed to carboxylic acid anhydride by the post baking. This improves developability and hardness of the cured film.

In addition, the development step may include a stage of performing the development, and a stage of exposing the cured film obtained by the development (hereinafter, also referred to as “post exposure”).

In a case where the development step includes a stage of performing the post exposure and a stage of performing the post baking, the post exposure and the post baking are preferably performed in this order.

Regarding the pattern exposure and the development, a description disclosed in paragraphs 0035 to 0051 of JP2006-023696A can be referred to, for example.

The preferred manufacturing method of the touch panel of the disclosure may include a step other than the steps described above. As the other step, a step (for example, washing step or the like) which may be provided in a normal photolithography step can be applied without any particular limitations.

(Image Display Device)

The image display device according to the disclosure comprises the capacitive input device according to the disclosure, preferably, the touch panel according to the disclosure (for example, touch panels of the first and second specific examples).

As the image display device according to the disclosure, a liquid crystal display device having a structure in which the touch panel according to the disclosure is overlapped on a well-known liquid crystal display element is preferable.

As the structure of the image display device comprising the touch panel, for example, a structure disclosed in “The latest Touch Panel Technology” (published 6 Jul. 2009, Techno Times), “Technologies and Developments of Touch Panels” supervised by Yuji Mitani, CMC Publishing CO., LTD. (2004, 12), FPD International 2009 Forum T-11 lecture text book, Cypress Semiconductor Corporation application note AN 2292 can be applied.

### EXAMPLES

Hereinafter, the disclosure will be described more specifically with reference to examples. The material, the amount used, the ratio, the process contents, the process procedure, and the like shown in the following examples can be suitably changed, within a range not departing from a gist of the disclosure. Accordingly, the range of the disclosure is not limited to specific examples shown below. “part” and “%” are based on mass, unless otherwise noted.

In the following examples, a weight-average molecular weight of a resin is a weight-average molecular weight obtained by performing polystyrene conversion of a value measured by gel permeation chromatography (GPC). In addition, a theoretical acid value was used for the acid value.

<Synthesis of Polymer>

First, as the resin in the photosensitive resin composition to be included in the photosensitive layer of the transfer film, polymers P-1 to P-5 which are specific examples of the polymer used in the disclosure were synthesized.

<<Synthesis of Polymer P-1>>244.2 parts by mass of propylene glycol monomethyl ether (MFG manufactured by Wako Pure Chemical Industries, Ltd.) was put into a three-necked flask and held at 90° C. under nitrogen. A mixed solution of 120.4 parts by mass of dicyclopentanyl methacrylate (manufactured by Tokyo Chemical Industry Co., Ltd.), 96.1 parts by mass of methacrylic acid (MAA, manufactured by Wako Pure Chemical Industries, Ltd.), 87.2 parts by mass of styrene (manufactured by Wako Pure Chemical Industries, Ltd.), 188.5 parts by mass of MFG 0.0610 parts by mass of p-methoxyphenol (manufactured by Wako Pure Chemical Industries, Ltd.), and 16.7 parts by mass of V-601 (dimethyl 2,2′-azobis(2-methyl propionate), manufactured by Wako Pure Chemical Industries, Ltd.) was added dropwise thereto over 3 hours.

After dropwise addition, the mixture was stirred at 90° C. for 1 hour, a mixed solution of V-601 (2.1 parts by mass) and MFG (5.2 parts by mass) was added, and after stirring for 1 hour, a mixed solution of V-601 (2.1 parts by mass) and MFG (5.2 parts by mass) was further added. After stirring for 1 hour, a mixed solution of V-601 (2.1 parts by mass) and MFG (5.2 parts by mass) was further added. After stirring for 3 hours, 2.9 parts by mass of MFG and 166.9 parts by mass of propylene glycol monomethyl ether acetate (PGMEA, manufactured by Daicel Chemical Industries, Ltd.) were added and stirred until it was homogenous.

1.5 parts by mass of tetramethylammonium bromide (TEAB, manufactured by Tokyo Chemical Industry Co., Ltd.) as an additive catalyst and 0.7 parts by mass of p-methoxyphenol were added to a reaction solution and a temperature was raised to 100° C. In addition, 62.8 parts by mass of glycidyl methacrylate (GMA, manufactured by Wako Pure Chemical Industries, Ltd.) was added and stirred at 100° C. for 9 hours to obtain a MFG/PGMEA mixed solution of the polymer P-1. The weight-average molecular weight of P-1 measured by GPC was 20,000 (in terms of polystyrene), and the concentration of solid contents was 36.3% by mass.

<<Synthesis of Polymers P-2 to P-5>>

The following polymers P-2 to P-5 were synthesized in the same manner as the synthesis of the polymer P-1. Each polymer was synthesized as a polymer solution, and the polymer concentration (concentration of solid contents) in the polymer solution was adjusted to 36.3% by mass.

The ratio of each constitutional unit in the following polymers P-1 to P-5 is a mass ratio. In addition, Me represents a methyl group.

Polymer P-1 (weight-average molecular weight: 20,000, number average molecular weight: 10,000)

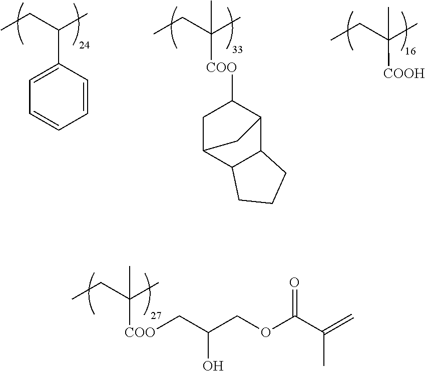

Polymer P-2 (weight-average molecular weight: 29,000, number average molecular weight: 12,500)

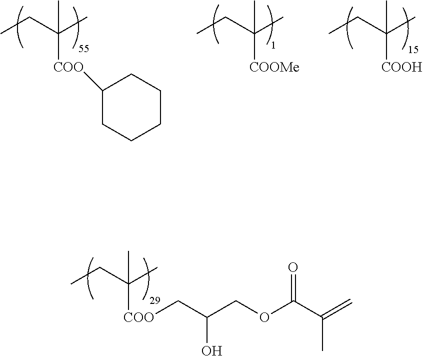

Polymer P-3 (weight-average molecular weight: 23,000, number average molecular weight: 11,000)

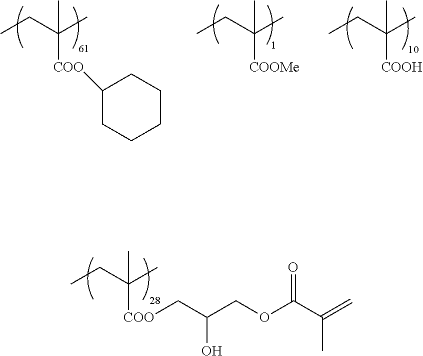

Polymer P-4 (weight-average molecular weight: 21,000, number average molecular weight: 10,500)

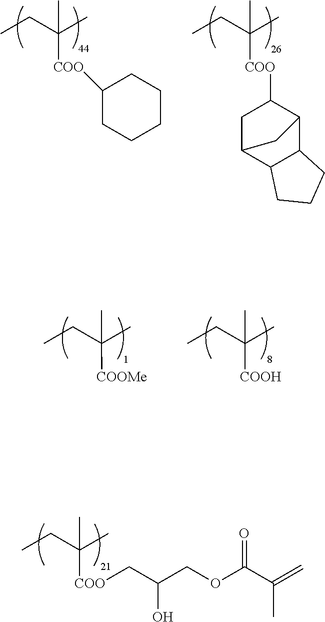

Polymer P-5 (weight-average molecular weight: 25,000, number average molecular weight: 11,500)

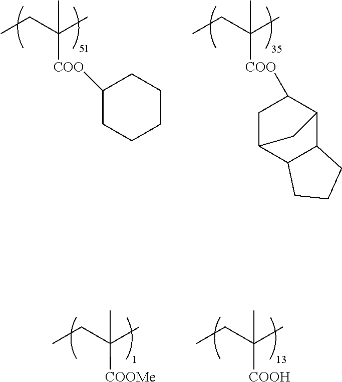

(Examples 1 to 30 and Comparative Examples 1 and 2)

<Preparation of Photosensitive Resin Composition>

Photosensitive resin compositions having the compositions shown in Tables 1 to 4 below were prepared. In Tables 1 to 4, the amount of the polymer means the amount of the polymer solution (polymer concentration: 36.3% by mass).

<Manufacturing of Transfer Film>

The obtained photosensitive resin composition was applied on a temporary support (LUMIRROR-16QS62, manufactured by Toray Industries Inc., thickness: 16 μm, polyethylene terephthalate film) by using a slit-shaped nozzle, and a photosensitive layer having a film thickness of 8 μm after drying was formed. A protective film (LUMIRROR-16QS62, manufactured by Toray Industries Inc., thickness: 16 μm, polyethylene terephthalate film) was pressure-bonded on the photosensitive layer, and each transfer film of Examples 1 to 30 and Comparative Examples 1 and 2 was manufactured.

<Evaluation of Water Vapor Transmission Rate (WVTR)>

Manufacturing of Sample for Measuring Moisture Permeability

The transfer film of each example and comparative example was laminated on PTFE (tetrafluoroethylene resin) membrane filter FP-100-100 manufactured by Sumitomo Electric Industries, Ltd., after the protective film is peeled off, and a laminate A having a laminated structure of “temporary support/photosensitive layer having a thickness of 8 μm/membrane filter” was formed. In the lamination conditions, a membrane filter temperature was set as 40° C., a laminating roll temperature was set as 110° C., a linear pressure was set as 3 N/cm, and a transportation speed was set as 2 m/min.

In addition, the temporary support was peeled off from the laminate A. Next, a step of laminating the transfer film, from which the protective film was peeled off, on the photosensitive layer in the same manner as described above and peeling off the temporary support was repeated three times. Subsequently, the transfer film, from which the protective film was peeled off, was laminated on the photosensitive layer in the same manner as described above to form a laminate B having a laminated structure of temporary support/photosensitive layer having a total film thickness of 40 μm/membrane filter.

The photosensitive layer of the obtained laminate B was exposed through the temporary support using a proximity type exposure machine (manufactured by Hitachi High-Tech Electronics Engineering Co., Ltd.) including an ultra-high pressure mercury lamp with an exposure intensity of 100 mJ/cm² (i ray). After the temporary support was peeled off, exposure was further performed with an exposure intensity of 375 mJ/cm2 (i ray), and post baking was performed at 145° C. for 30 minutes to cure the photosensitive layer, thereby forming a cured film.

Accordingly, a sample for measuring moisture permeability having a laminated structure of “cured film having a total film thickness of 40 μm/membrane filter” was obtained.

Measurement of Water Vapor Transmission Rate (WVTR)

The measurement of the moisture permeability was performed by a cup method using the sample for measuring moisture permeability, with reference to JIS-Z-0208 (1976). Hereinafter, the details will be described.

First, a circular sample having a diameter of 70 mm was cut from the sample for measuring moisture permeability. Next, 20 g of dried calcium chloride was put in a measurement cup, and covered with the circular sample, and accordingly, a lid-attached measurement cup was prepared.

This lid-attached measurement cup was left in a constant-temperature and constant-humidity tank for 24 hours under the condition of 65° C. with 90% RH. The water vapor transmission rate (WVTR) of the circular sample (unit: g/m²·day) was calculated from a change in mass of the lid-attached measurement cup before and after the leaving.

The measurement described above was performed three times and an average value of the WVTRs in three times of the measurement was calculated. The water vapor transmission rate (WVTR) was evaluated based on the average value of the WVTR according to the evaluation standards. In the evaluation criteria below, any one of A and B is suitable for practical use, and A is most preferable.

The evaluation results are shown in Tables 1 to 4.

In the measurement, the WVTR of the circular sample having a laminated structure of “cured film/membrane filter” was measured as described above. However, the WVTR of the membrane filter is extremely higher than the WVTR of the cured film, and accordingly, in the measurement, the WVTR of the cured film is substantially measured.

Evaluation Standard of Water Vapor Transmission Rate (WVTR)

A: Average value of WVTR is less than 200 g/m²·day

B: Average value of WVTR is 200 g/m²·day or more and less than 300 g/m²·day

C: Average value of WVTR is 300 g/m²·day or more

<Evaluation of Developability (Development Residue Attachment Amount)>

The protective film was peeled off from each transfer film of examples and comparative examples, and the transfer film, from which the protective film was peeled off, was laminated on a cycloolefin resin film, on which a copper foil was laminated under laminating conditions of a roll temperature of 110° C., a linear pressure of 0.6 MPa, and a linear velocity of 2.0 m/min, thereby transferring the photosensitive layer of the transfer film to a surface of the copper foil.

The temporary support was peeled off from the laminate and developed using a 1% by mass aqueous solution of sodium carbonate (liquid temperature 30° C.) as a developer for 45 seconds, thereby removing the photosensitive layer. In addition, air was blown to remove water.

The surface of the copper foil after development and removal of the photosensitive layer was observed with an optical microscope (10× magnification) to confirm a development residue. The development residue was evaluated according to the following evaluation standard based on the confirmed result.

In the evaluation criteria below, any one of A and B is suitable for practical use, and A is most preferable.

The evaluation results are shown in Tables 1 to 4.

Evaluation Standard of Development Residue

A: The density of development residue on the surface of the copper foil after development and removal of the photosensitive layer was 0 pieces/1 cm² (no development residue was observed).

B: The density of the development residue on the surface of the copper foil after development and removal of the photosensitive layer was more than 0 pieces/1 cm² and less than 5 pieces/1 cm².

C: The density of development residue on the surface of the copper foil after development and removal of the photosensitive layer was 5 pieces/1 cm² or more.

TABLE 1

| | | Example | | | | | | | |
|---|---|---|---|---|---|---|---|---|---|
| | | 1 | 2 | 3 | 4 | 5 | 6 | 7 | 8 |
| Ethylenically | M-1 | 5.53 | 5.53 | 5.53 | 5.53 | 5.53 | 5.53 | 5.53 | 5.53 |
| unsaturated | M-2 | 2.76 | 2.76 | 2.76 | 2.76 | 2.76 | 2.76 | 2.76 | 2.76 |
| compound | M-3 | 0.92 | 0.92 | 0.92 | 0.92 | 0.92 | 0.92 | 0.92 | 0.92 |
| | M-4 | — | — | — | — | — | — | — | — |
| Binder | P-1(acid value 103 mgKOH/g) | 42.31 | 42.31 | 42.31 | 42.31 | 42.31 | 42.31 | 42.31 | 42.31 |
| polymer | P-2(acid value 95 mgKOH/g) | — | — | — | — | — | — | — | — |
| | P-3(acid value 65 mgKOH/g) | — | — | — | — | — | — | — | — |
| | P-4(acid value 55 mgKOH/g) | — | — | — | — | — | — | — | — |
| | P-5(acid value 88 mgKOH/g) | — | — | — | — | — | — | — | — |
| Photopoly- | I-1 | 0.11 | 0.11 | 0.11 | 0.11 | 0.11 | 0.11 | 0.11 | 0.11 |
| merization | I-2 | 0.21 | 0.21 | 0.21 | 0.21 | 0.21 | 0.21 | 0.21 | 0.21 |
| initiator | I-3 | — | — | — | — | — | — | — | — |
| | I-4 | — | — | — | — | — | — | — | — |
| Blocked | A-1 | 6.04 | — | — | — | — | — | — | — |
| isocyanate | A-2 | — | 6.04 | — | — | — | — | — | — |
| compound | A-3 | — | — | 6.04 | — | — | — | — | — |
| | A-4 | — | — | — | 6.04 | — | — | — | — |
| | A-5 | — | — | — | — | 6.04 | — | — | — |
| | A-6 | — | — | — | — | — | 6.04 | — | — |
| | A-7 | — | — | — | — | — | — | 6.04 | — |
| | A-8 | — | — | — | — | — | — | — | 6.04 |
| | A-9 | — | — | — | — | — | — | — | — |
| | A-10 | — | — | — | — | — | — | — | — |
| | A-11 | — | — | — | — | — | — | — | — |
| | A-12 | — | — | — | — | — | — | — | — |
| | A-13 | — | — | — | — | — | — | — | — |
| | A-14 | — | — | — | — | — | — | — | — |
| Other | N-phenylglycine | 0.03 | 0.03 | 0.03 | 0.03 | 0.03 | 0.03 | 0.03 | 0.03 |
| component | (manufactured by | | | | | | | | |
| | JUNSEI CHEMICAL | | | | | | | | |
| | CO., LTD.) | | | | | | | | |
| | 1,2,4-triazole | 0.06 | 0.06 | 0.06 | 0.06 | 0.06 | 0.06 | 0.06 | 0.06 |
| | (manufactured by | | | | | | | | |
| | Otsuka Chemical | | | | | | | | |
| | Co., Ltd.) | | | | | | | | |
| | Benzimidazole | — | — | — | — | — | — | — | — |
| | (manufactured by | | | | | | | | |
| | Tokyo Chemical | | | | | | | | |
| | Industry Co., Ltd.) | | | | | | | | |
| | 5-amino-1H-tetrazole | — | — | — | — | — | — | — | — |
| | (HAT, manufactured by | | | | | | | | |
| | TOYOBO CO., LTD.) | | | | | | | | |
| | Karenz MT-BD1 | — | — | — | — | — | — | — | — |
| | (manufactured by | | | | | | | | |
| | Showa Denko K.K., | | | | | | | | |
| | thiol compound) | | | | | | | | |
| | SMA EF-40 | 0.35 | 0.35 | 0.35 | 0.35 | 0.35 | 0.35 | 0.35 | 0.35 |
| | (manufactured by | | | | | | | | |
| | Cray Valley) | | | | | | | | |
| | MEGAFACE F551A | 0.16 | 0.16 | 0.16 | 0.16 | 0.16 | 0.16 | 0.16 | 0.16 |
| | (manufactured by | | | | | | | | |
| | DIC Corporation) * | | | | | | | | |
| | 30% PGMEA solution | | | | | | | | |
| Solvent | Methyl ethyl ketone | 41.52 | 41.52 | 41.52 | 41.52 | 41.52 | 41.52 | 41.52 | 41.52 |

| | | | | | | | | |
|---|---|---|---|---|---|---|---|---|
| Value of N_{C}/N_{B} | 0.25 | 0.10 | 0.40 | 0.33 | 0.60 | 0.40 | 0.25 | 0.25 |
| Evaluation of moisture permeability | A | A | A | A | A | A | A | A |
| Evaluation of developability | A | B | A | A | A | A | A | A |

TABLE 2

| | | Example | | | | | | | |
|---|---|---|---|---|---|---|---|---|---|
| | | 9 | 10 | 11 | 12 | 13 | 14 | 15 | 16 |
| Ethylenically | M-1 | 5.53 | 5.53 | 5.53 | 5.53 | 5.53 | 5.53 | 5.53 | 5.53 |
| unsaturated | M-2 | 2.76 | 2.76 | 2.76 | 2.76 | 2.76 | 2.76 | 2.76 | 2.76 |
| compound | M-3 | 0.92 | 0.92 | 0.92 | 0.92 | 0.92 | 0.92 | 0.92 | 0.92 |
| | M-4 | — | — | — | — | — | — | — | — |
| Binder | P-1 (acid value 103 mgKOH/g) | 42.31 | 42.31 | 42.31 | 42.31 | 42.31 | 49.90 | 48.31 | 36.32 |
| polymer | P-2 (acid value 95 mgKOH/g) | — | — | — | — | — | — | — | — |
| | P-3 (acid value 65 mgKOH/g) | — | — | — | — | — | — | — | — |
| | P-4 (acid value 55 mgKOH/g) | — | — | — | — | — | — | — | — |
| | P-5 (acid value 88 mgKOH/g) | — | — | — | — | — | — | — | — |
| Photopoly- | I-1 | 0.11 | 0.11 | 0.11 | 0.11 | 0.11 | 0.11 | 0.11 | 0.11 |
| merization | I-2 | 0.21 | 0.21 | 0.21 | 0.21 | 0.21 | 0.21 | 0.21 | 0.21 |
| initiator | I-3 | — | — | — | — | — | — | — | — |
| | I-4 | — | — | — | — | — | — | — | — |
| Blocked | A-1 | — | — | — | — | — | 1.45 | 2.42 | 9.67 |
| isocyanate | A-2 | — | — | — | — | — | — | — | — |
| compound | A-3 | — | — | — | — | — | — | — | — |
| | A-4 | — | — | — | — | — | — | — | — |
| | A-5 | — | — | — | — | — | — | — | — |
| | A-6 | — | — | — | — | — | — | — | — |
| | A-7 | — | — | — | — | — | — | — | — |
| | A-8 | — | — | — | — | — | — | — | — |
| | A-9 | 6.04 | — | — | — | — | — | — | — |
| | A-10 | — | 6.04 | — | — | — | — | — | — |
| | A-11 | — | — | 6.04 | — | — | — | — | — |
| | A-12 | — | — | — | 6.04 | — | — | — | — |
| | A-13 | — | — | — | — | 6.04 | — | — | — |
| | A-14 | — | — | — | — | — | — | — | — |
| Other | N-phenylglycine | 0.03 | 0.03 | 0.03 | 0.03 | 0.03 | 0.03 | 0.03 | 0.03 |
| component | (manufactured by | | | | | | | | |
| | JUNSEI CHEMICAL | | | | | | | | |
| | CO., LTD.) | | | | | | | | |
| | 1,2,4-triazole | 0.06 | 0.06 | 0.06 | 0.06 | 0.06 | 0.06 | 0.06 | 0.06 |
| | (manufactured by | | | | | | | | |
| | Otsuka Chemical | | | | | | | | |
| | Co., Ltd.) | | | | | | | | |
| | Benzimidazole | — | — | — | — | — | — | — | — |
| | (manufactured by | | | | | | | | |
| | Tokyo Chemical Industry | | | | | | | | |
| | Co., Ltd.) | | | | | | | | |
| | 5-amino-1H-tetrazole | — | — | — | — | — | — | — | — |
| | (HAT, manufactured by | | | | | | | | |
| | TOYOBO CO., LTD.) | | | | | | | | |
| | Karenz MT-BD1 | — | — | — | — | — | — | — | — |
| | (manufactured by | | | | | | | | |
| | Showa Denko K.K., | | | | | | | | |
| | thiol compound) | | | | | | | | |
| | SMA EF-40 | 0.35 | 0.35 | 0.35 | 0.35 | 0.35 | 0.35 | 0.35 | 0.35 |
| | (manufactured by | | | | | | | | |
| | Cray Valley) | | | | | | | | |
| | MEGAFACE F551A | 0.16 | 0.16 | 0.16 | 0.16 | 0.16 | 0.16 | 0.16 | 0.16 |
| | (manufactured by | | | | | | | | |
| | DIC Corporation) * | | | | | | | | |
| | 30% PGMEA solution | | | | | | | | |
| Solvent | Methyl ethyl ketone | 41.52 | 41.52 | 41.52 | 41.52 | 41.52 | 38.52 | 39.15 | 43.89 |

| | | | | | | | | |
|---|---|---|---|---|---|---|---|---|
| Value of N_{C}/N_{B} | 0.25 | 0.25 | 0.25 | 0.25 | 0.50 | 0.25 | 0.25 | 0.25 |
| Evaluation of moisture permeability | A | A | A | A | B | B | A | A |
| Evaluation of developability | A | A | A | A | A | A | A | A |

TABLE 3

| | | Example | | | | | | | |
|---|---|---|---|---|---|---|---|---|---|
| | | 17 | 18 | 19 | 20 | 21 | 22 | 23 | 24 |
| Ethylenically | M-1 | 5.53 | 5.53 | 5.53 | 5.53 | 5.53 | 5.53 | 5.53 | 5.53 |
| unsaturated | M-2 | 2.76 | 2.76 | 2.76 | 2.76 | — | 2.76 | 2.76 | 2.76 |
| compound | M-3 | 0.92 | 0.92 | 0.92 | 0.92 | 0.92 | 0.92 | 0.92 | 0.92 |
| | M-4 | — | — | — | — | 2.76 | — | — | — |
| Binder | P-1 (acid value 103 mgKOH/g) | — | — | — | — | 42.31 | 42.31 | 42.31 | 42.31 |
| polymer | P-2 (acid value 95 mgKOH/g) | 42.31 | — | — | — | — | — | — | — |
| | P-3 (acid value 65 mgKOH/g) | — | 42.31 | — | — | — | — | — | — |
| | P-4 (acid value 55 mgKOH/g) | — | — | 42.31 | — | — | — | — | — |
| | P-5 (acid value 88 mgKOH/g) | — | — | — | 42.31 | — | — | — | — |
| Photopoly- | I-1 | 0.11 | 0.11 | 0.11 | 0.11 | 0.11 | — | — | 0.11 |
| merization | I-2 | 0.21 | 0.21 | 0.21 | 0.21 | 0.21 | 0.21 | — | 0.21 |
| initiator | I-3 | — | — | — | — | — | 0.11 | — | — |
| | I-4 | — | — | — | — | — | — | 0.32 | — |
| Blocked | A-1 | 6.04 | 6.04 | 6.04 | 6.04 | 6.04 | 6.04 | 6.04 | 6.04 |
| isocyanate | A-2 | — | — | — | — | — | — | — | — |
| compound | A-3 | — | — | — | — | — | — | — | — |
| | A-4 | — | — | — | — | — | — | — | — |
| | A-5 | — | — | — | — | — | — | — | — |
| | A-6 | — | — | — | — | — | — | — | — |
| | A-7 | — | — | — | — | — | — | — | — |
| | A-8 | — | — | — | — | — | — | — | — |
| | A-9 | — | — | — | — | — | — | — | — |
| | A-10 | — | — | — | — | — | — | — | — |
| | A-11 | — | — | — | — | — | — | — | — |
| | A-12 | — | — | — | — | — | — | — | — |
| | A-13 | — | — | — | — | — | — | — | — |
| | A-14 | — | — | — | — | — | — | — | — |
| Other | N-phenylglycine | 0.03 | 0.03 | 0.03 | 0.03 | 0.03 | 0.03 | 0.03 | 0.03 |
| component | (manufactured by | | | | | | | | |
| | JUNSEI CHEMICAL | | | | | | | | |
| | CO., LTD.) | | | | | | | | |
| | 1,2,4-triazole | 0.06 | 0.06 | 0.06 | 0.06 | 0.06 | 0.06 | 0.06 | — |
| | (manufactured by | | | | | | | | |
| | Otsuka Chemical | | | | | | | | |
| | Co., Ltd.) | | | | | | | | |
| | Benzimidazole | — | — | — | — | — | — | — | 0.06 |
| | (manufactured by | | | | | | | | |
| | Tokyo Chemical Industry | | | | | | | | |
| | Co., Ltd.) | | | | | | | | |
| | 5-amino-1H-tetrazole | — | — | — | — | — | — | — | — |
| | (HAT, manufactured by | | | | | | | | |
| | TOYOBO CO., LTD.) | | | | | | | | |
| | Karenz MT-BD1 | — | — | — | — | — | — | — | — |
| | (manufactured by | | | | | | | | |
| | Showa Denko K.K., | | | | | | | | |
| | thiol compound) | | | | | | | | |
| | SMA EF-40 | 0.35 | 0.35 | 0.35 | 0.35 | 0.35 | 0.35 | 0.35 | 0.35 |
| | (manufactured by | | | | | | | | |
| | Cray Valley) | | | | | | | | |
| | MEGAFACE F551A | 0.16 | 0.16 | 0.16 | 0.16 | 0.16 | 0.16 | 0.16 | 0.16 |
| | (manufactured by | | | | | | | | |
| | DIC Corporation) * | | | | | | | | |
| | 30% PGMEA solution | | | | | | | | |
| Solvent | Methyl ethyl ketone | 41.52 | 41.52 | 41.52 | 41.52 | 41.52 | 41.52 | 41.52 | 41.52 |

| | | | | | | | | |
|---|---|---|---|---|---|---|---|---|
| Value of N_{C}/N_{B} | 0.25 | 0.25 | 0.25 | 0.25 | 0.25 | 0.25 | 0.25 | 0.25 |
| Evaluation of moisture permeability | A | A | A | B | A | A | A | A |
| Evaluation of developability | A | A | B | A | A | A | A | A |

TABLE 4

| | | | | | | | | Comparative | |
|---|---|---|---|---|---|---|---|---|---|
| | | Example | | | | | | example | |
| | | 25 | 26 | 27 | 28 | 29 | 30 | 1 | 2 |
| Ethylenically | M-1 | 5.53 | 2.76 | — | 4.61 | 5.53 | 5.53 | 5.53 | 5.53 |
| unsaturated | M-2 | — | 2.76 | 2.76 | 2.76 | 2.76 | 2.76 | 2.76 | 2.76 |
| compound | M-3 | 0.92 | 0.92 | 0.92 | 1.84 | — | 0.92 | 0.92 | 0.92 |
| | M-4 | — | 2.76 | 5.53 | — | 0.92 | — | — | — |
| Binder | P-1 (acid value 103 mgKOH/g) | 42.31 | 42.31 | 42.31 | 42.31 | 42.31 | 43.51 | 42.31 | 52.30 |
| polymer | P-2 (acid value 95 mgKOH/g) | — | — | — | — | — | — | — | — |
| | P-3 (acid value 65 mgKOH/g) | — | — | — | — | — | — | — | — |
| | P-4 (acid value 55 mgKOH/g) | — | — | — | — | — | — | — | — |
| | P-5 (acid value 88 mgKOH/g) | — | — | — | — | — | — | — | — |
| Photopoly- | I-1 | 0.11 | 0.11 | 0.11 | 0.11 | 0.11 | 0.11 | 0.11 | 0.11 |
| merization | I-2 | 0.21 | 0.21 | 0.21 | 0.21 | 0.21 | 0.21 | 0.21 | 0.21 |
| initiator | I-3 | — | — | — | — | — | — | — | — |
| | I-4 | — | — | — | — | — | — | — | — |
| Blocked | A-1 | 6.04 | 6.04 | 6.04 | 6.04 | 6.04 | 6.04 | — | — |
| isocyanate | A-2 | — | — | — | — | — | — | — | — |
| compound | A-3 | — | — | — | — | — | — | — | — |
| | A-4 | — | — | — | — | — | — | — | — |
| | A-5 | — | — | — | — | — | — | — | — |
| | A-6 | — | — | — | — | — | — | — | — |
| | A-7 | — | — | — | — | — | — | — | — |
| | A-8 | — | — | — | — | — | — | — | — |
| | A-9 | — | — | — | — | — | — | — | — |
| | A-10 | — | — | — | — | — | — | — | — |
| | A-11 | — | — | — | — | — | — | — | — |
| | A-12 | — | — | — | — | — | — | — | — |
| | A-13 | — | — | — | — | — | — | — | — |
| | A-14 | — | — | — | — | — | — | 6.04 | — |
| Other | N-phenylglycine | 0.03 | 0.03 | 0.03 | 0.03 | 0.03 | — | 0.03 | 0.03 |
| component | (manufactured by | | | | | | | | |
| | JUNSEI CHEMICAL | | | | | | | | |
| | CO., LTD.) | | | | | | | | |
| | 1,2,4-triazole | — | 0.06 | 0.06 | 0.06 | 0.06 | — | 0.06 | 0.06 |
| | (manufactured by | | | | | | | | |
| | Otsuka Chemical | | | | | | | | |
| | Co., Ltd.) | | | | | | | | |
| | Benzimidazole | — | — | — | — | — | — | — | — |
| | (manufactured by | | | | | | | | |
| | Tokyo Chemical Industry | | | | | | | | |
| | Co., Ltd.) | | | | | | | | |
| | 5-amino-1H-tetrazole | 0.06 | — | — | — | — | — | — | — |
| | (HAT, manufactured by | | | | | | | | |
| | TOYOBO CO., LTD.) | | | | | | | | |
| | Karenz MT-BD1 | 2.76 | — | — | — | — | — | — | — |
| | (manufactured by | | | | | | | | |
| | Showa Denko K.K., | | | | | | | | |
| | thiol compound) | | | | | | | | |
| | SMA EF-40 | 0.35 | 0.35 | 0.35 | 0.35 | 0.35 | — | 0.35 | 0.35 |
| | (manufactured by | | | | | | | | |
| | Cray Valley) | | | | | | | | |
| | MEGAFACE F551A | 0.16 | 0.16 | 0.16 | 0.16 | 0.16 | 0.16 | 0.16 | 0.16 |
| | (manufactured by | | | | | | | | |
| | DIC Corporation) * | | | | | | | | |
| | 30% PGMEA solution | | | | | | | | |
| Solvent | Methyl ethyl ketone | 41.52 | 41.52 | 41.52 | 41.52 | 41.52 | 40.76 | 41.52 | 37.58 |

| | | | | | | | | |
|---|---|---|---|---|---|---|---|---|
| Value of N_{C}/N_{B} | 0.25 | 0.25 | 0.25 | 0.25 | 0.25 | 0.25 | 0.00 | — |
| Evaluation of moisture permeability | A | A | A | A | A | A | A | C |
| Evaluation of developability | A | A | A | A | A | A | C | A |

A value of N_{C}/N_{B} in Tables 1 to 4 is a value of a ratio N_{C}/N_{B} of a functional group number N_{C} of a carboxylic acid group included in the blocked isocyanate compound to a total N_{B} of a functional group number of blocked isocyanate groups and a functional group number of the polymerizable group included in the blocked isocyanate compound.

Hereinafter, details of abbreviations shown in Tables 1 to 4 other than the above will be described.

M-1: tricyclodecane dimethanol diacrylate (A-DCP, manufactured by Shin-Nakamura Chemical Co., Ltd.)

M-2: Urethane acrylate (8UX-015A, manufactured by Taisei Fine Chemical Co., Ltd.) M-3: Carboxylic acid group-containing monomer (Aronix TO-2349, manufactured by Toagosei Co., Ltd.)

M-4: Ditrimethylolpropane tetraacrylate (AD-TMP, manufactured by Shin-Nakamura Chemical Co., Ltd.)

I-1: 1-[9-ethyl-6-(2-methylbenzoyl)-9H-carbazole-3-yl]ethanone-1-(O-acetyloxime) (OXE-02, manufactured by BASF)

I-2: 2-methyl-1-(4-methylthiophenyl)-2-morpholinopropan-1-one (Irgacure 907, manufactured by BASF)

I-3: 1-[4-(phenylthio)phenyl]-1,2-octanedione-2-(O-benzoyloxime) (OXE-01, manufactured by BASF)

I-4:

2-(dimethylamino)-2-[(4-methylphenyl)methyl]-1-[4-(4-morpholinyl)phenyl]-1-butanone (Irgacure379EG, manufactured by BASF)

A-1 to A-13: A-1 to A-13 described above as specific examples of the blocked isocyanate compound

A-14: Blocked isocyanate compound not having the following carboxylic acid group

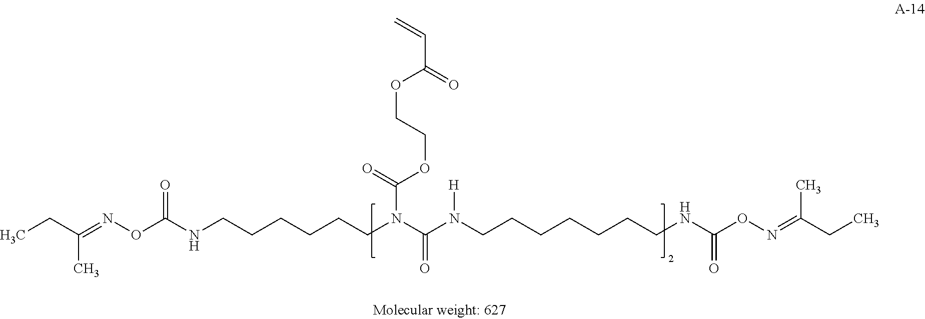

From the results shown in Tables 1 to 4, it is found that, the photosensitive resin compositions of Examples 1 to 30 have excellent developability and low moisture permeability of the cured film to be obtained, compared to the photosensitive resin compositions of the comparative examples.

### EXPLANATION OF REFERENCES

10: transfer film
12: temporary support
16: protective film
18, 18A: photosensitive layer (electrode protective film for touch panel)
20, 20A: Second resin layer (first refractive index adjusting layer)
30: touch panel
32: substrate
34: transparent electrode pattern
36: second refractive index adjusting layer
40: first region where transparent electrode pattern is present
42: second region where transparent electrode pattern is not present
56: leading wiring
70: first transparent electrode pattern
72: second transparent electrode pattern
74: image display region
75: image non-display region
90: touch panel

What is claimed is:

1. A photosensitive resin composition comprising:
a binder polymer;
an ethylenically unsaturated compound having no blocked isocyanate group;
a photopolymerization initiator; and
a blocked isocyanate compound,
wherein the blocked isocyanate compound has a carboxylic acid group.

2. The photosensitive resin composition according to claim 1,
wherein a weight-average molecular weight of the blocked isocyanate compound is 4,000 or less.

3. The photosensitive resin composition according to claim 1,
wherein the blocked isocyanate compound includes at least one structure selected from the group consisting of a biuret bond, an allophanate bond, and an isocyanuric ring structure.

4. The photosensitive resin composition according to claim 1,
wherein a number of blocked isocyanate groups in the blocked isocyanate compound is 1 to 10.

5. The photosensitive resin composition according to claim 1,
wherein the blocked isocyanate compound further includes a polymerizable group.

6. The photosensitive resin composition according to claim 5,
wherein the polymerizable group in the blocked isocyanate compound is an ethylenically unsaturated group.

7. The photosensitive resin composition according to claim 6,
wherein the polymerizable group in the blocked isocyanate compound includes a partial structure represented by following formula (B-2), 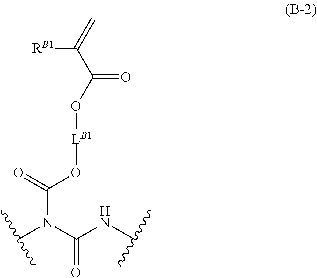
in the formula (B-2), R^{B1} represents a hydrogen atom or a methyl group, L^{B1} represents an alkylene group having 2 to 8 carbon atoms.

8. The photosensitive resin composition according to claim 5,
wherein a value of a ratio N_{C}/N_{B} of a functional group number N_{C} of carboxylic acid groups included in the blocked isocyanate compound to a total N_{B} of a functional group number of blocked isocyanate groups and a functional group number of the polymerizable groups included in the blocked isocyanate compound is 0.1 or more.

9. The photosensitive resin composition according to claim 1,
wherein a weight-average molecular weight of the blocked isocyanate compound is 500 or more.

10. The photosensitive resin composition according to claim 1,
wherein a content of the blocked isocyanate compound is 5% by mass or more with respect to a total solid content of the photosensitive resin composition.

11. The photosensitive resin composition according to claim 1,
wherein the binder polymer is an alkali-soluble resin having an acid value of 60 mgKOH/g or more.

12. The photosensitive resin composition according to claim 1,
wherein the binder polymer is a resin having a constitutional unit including an ethylenically unsaturated group.

13. A cured film obtained by curing a solid content of the photosensitive resin composition according to claim 1.

14. The cured film according to claim 13,
wherein the cured film is a protective film for a touch panel.

15. A laminate formed by laminating a substrate, an electrode, and the cured film according to claim 13 in order.

16. The laminate according to claim 15,
wherein the electrode is an electrode of a capacitive input device.

17. A transfer film comprising:
a temporary support; and
a layer including the photosensitive resin composition according to claim 1.

18. A manufacturing method for a touch panel, comprising:
preparing a substrate for a touch panel having a structure in which at least one of an electrode for a touch panel or a wiring for a touch panel is disposed on the substrate;
forming a photosensitive layer on a surface of the substrate for a touch panel on a side where at least one of the electrode for a touch panel or the wiring for a touch panel is disposed, using the transfer film according to claim 17;
performing patternwise exposing on the photosensitive layer formed on the substrate for a touch panel to light; and
developing the patternwise exposed photosensitive layer to obtain a protective film for a touch panel protecting at least a part of at least one of the electrode for a touch panel or the wiring for a touch panel.
